(19) United States
(12) Patent Application Publication
(10) Pub. No.: US 2024/0365587 A1
(43) Pub. Date: Oct. 31, 2024

(54) DISPLAY SUBSTRATE AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Dan CAO, Beijing (CN); Xiaoqing SHU, Beijing (CN); Wenhui GAO, Beijing (CN); Yonglin GUO, Beijing (CN); Yunsheng XIAO, Beijing (CN)

(73) Assignees: CHENGDU BOE OPTOELECTRONICS TECHNOLOGY CO., LTD., Sichuan (CN); BOE TECHNOLOGY GROUP CO., LTD., Beijing (CN)

(21) Appl. No.: 18/291,922

(22) PCT Filed: Apr. 24, 2023
(86) PCT No.: PCT/CN2023/090332

§ 371 Date: Jan. 25, 2024

(30) Foreign Application Priority Data
May 18, 2022 (CN) 202210540045.2

(51) Int. Cl. H10K 59/121; G09G 3/3233; H10K 59/131

(52) U.S. Cl. CPC H10K 59/1213; G09G 3/3233; H10K 59/131; G09G 2300/0842; G09G 2320/0233

(57) ABSTRACT

A display substrate includes pixel circuits and light-emitting devices. The pixel circuits include first pixel circuits and second pixel circuits. The light-emitting devices include first light-emitting devices and second light-emitting devices. A first pixel circuit is coupled to a first light-emitting device, and the first pixel circuit is at least partially opposite to the first light-emitting device. A second pixel circuit is coupled to a second light-emitting device, and an orthographic projection of the second pixel circuit and an orthographic projection of the second light-emitting device have no overlap. A width-to-length ratio of a channel of a driving transistor in the first pixel circuit is greater than a width-to-length ratio of a channel of a driving transistor in the second pixel circuit; and/or a channel capacitance of a compensation transistor in the first pixel circuit is larger than a channel capacitance of a compensation transistor in the second pixel circuit.

This application claims priority to Chinese Patent Application No. 202210540045.2, filed on May 18, 2022, which is incorporated herein by reference in its entirety.

### TECHNICAL FIELD

The present disclosure relates to the field of display technologies, and in particular, to a display substrate and a display apparatus.

### BACKGROUND

An organic light emitting diode (OLED) display technology is a technology that uses luminescent materials to emit light under driven of a current for display. OLED displays have ultra-light, ultra-thin, high brightness, wide viewing angle, low voltage, low power consumption, fast response, high definition, shock-resistant, bendable, low cost, simple process, few raw materials used, high luminous efficiency, wide temperature range, and other advantages.

### SUMMARY

In an aspect, a display substrate is provided. The display substrate includes a plurality of pixel circuits and a plurality of light-emitting devices. The pixel circuits each include a driving transistor and a compensation transistor coupled to the driving transistor. The plurality of pixel circuits include a plurality of first pixel circuits and a plurality of second pixel circuits. The plurality of light-emitting devices include a plurality of first light-emitting devices and a plurality of second light-emitting devices. A first pixel circuit is coupled to a first light-emitting device, and the first pixel circuit is disposed at least partially directly opposite to the first light-emitting device. A second pixel circuit is coupled to a second light-emitting device, and an orthographic projection of the second pixel circuit on a plane where the display substrate is located and an orthographic projection of the second light-emitting device on the plane where the display substrate is located have no overlap. A width-to-length ratio of a channel of a driving transistor in the first pixel circuit is greater than a width-to-length ratio of a channel of a driving transistor in the second pixel circuit; and/or a channel capacitance of a compensation transistor in the first pixel circuit is larger than a channel capacitance of a compensation transistor in the second pixel circuit.

In some embodiments, a channel width of the driving transistor in the first pixel circuit is larger than a channel width of the driving transistor in the second pixel circuit.

In some embodiments, a difference between the channel width of the driving transistor in the first pixel circuit and the channel width of the driving transistor in the second pixel circuit is less than or equal to 0.6 μm.

In some embodiments, a ratio of a channel width of the driving transistor in the first pixel circuit to a channel width of the driving transistor in the second pixel circuit is greater than 1 and less than or equal to 1.21.

In some embodiments, a channel length of the driving transistor in the first pixel circuit is smaller than a channel length of the driving transistor in the second pixel circuit.

In some embodiments, a difference between the channel length of the driving transistor in the first pixel circuit and the channel length of the driving transistor in the second pixel circuit is less than or equal to 1.4 μm.

In some embodiments, a ratio of a channel length of the driving transistor in the first pixel circuit to a channel length of the driving transistor in the second pixel circuit is less than 1 and greater than or equal to 0.94.

In some embodiments, a channel width of the compensation transistor in the first pixel circuit is larger than a channel width of the compensation transistor in the second pixel circuit.

In some embodiments, a difference between the channel width of the compensation transistor in the first pixel circuit and the channel width of the compensation transistor in the second pixel circuit is less than or equal to 0.3 μm.

In some embodiments, a ratio of the channel width of the compensation transistor in the first pixel circuit to the channel width of the compensation transistor in the second pixel circuit is greater than 1 and less than or equal to 1.14.

In some embodiments, a channel length of the compensation transistor in the first pixel circuit is larger than a channel length of the compensation transistor in the second pixel circuit.

In some embodiments, a difference between the channel length of the compensation transistor in the first pixel circuit and the channel length of the compensation transistor in the second pixel circuit is less than or equal to 0.8 μm.

In some embodiments, a ratio of the channel length of the compensation transistor in the first pixel circuit to the channel length of the compensation transistor in the second pixel circuit is greater than 1 and less than or equal to 1.15.

In some embodiments, the display substrate further includes a plurality of leads. The second pixel circuit is coupled to the second light-emitting device by a lead.

In some embodiments, width-to-length ratios of channels of driving transistors in the second pixel circuits are negatively correlated to length ratios of the leads respectively connected to the second pixel circuits; and/or channel capacitances of compensation transistors in the second pixel circuits are negatively correlated to the length ratios of the leads respectively connected to the second pixel circuits.

In some embodiments, the pixel circuits each further include a first reset transistor, a first light emission control transistor, a second light emission control transistor, a second reset transistor, a switch transistor and a storage capacitor. A gate of the first reset transistor is coupled to a first reset signal line, a first electrode of the first reset transistor is coupled to a first initial signal line, and a second electrode of the first reset transistor is coupled to a first node. The first reset transistor is configured to transmit a first initial signal provided by the first initial signal line to the first node under control of a first reset signal provided by the first reset signal line. A gate of the switch transistor is coupled to a scanning signal line, a first electrode of the switch transistor is coupled to a data signal line, and a second electrode of the switch transistor is coupled to a second node. The switch transistor is configured to transmit a data signal provided by the data signal line to the second node under control of a scanning signal provided by the scanning signal line. A gate of the first light emission control transistor is coupled to an enable signal line, a first electrode of the first light emission control transistor is coupled to a first voltage signal line, and a second electrode of the first light emission control transistor is coupled to the second node. The first light emission control transistor is configured to transmit a first voltage signal provided by the first voltage signal line to the second node under control of an enable signal provided by the enable signal line. A gate of the driving transistor is coupled to the first node, a first electrode of the driving transistor is coupled to the second node, and a second electrode of the driving transistor is coupled to a third node. The driving transistor is configured to transmit an electrical signal at the second node to the third node under control of an electrical signal at the first node. A gate of the compensation transistor is coupled to the first node, a first electrode of the compensation transistor is coupled to the third node, and a second electrode of the compensation transistor is coupled to the scanning signal line. The compensation transistor is configured to transmit an electrical signal at the third node to the first node under the control of the scanning signal. A first electrode plate of the storage capacitor is coupled to the first voltage signal line, and a second electrode plate of the storage capacitor is coupled to the first node. A gate of the second light emission control transistor is coupled to the enable signal line, a first electrode of the second light emission control transistor is coupled to the third node, and a second electrode of the second light emission control transistor is coupled to a fourth node. The second light emission control transistor is configured to transmit the electrical signal at the third node to the fourth node under the control of the enable signal. A gate of the second reset transistor is coupled to a second reset signal line, a first electrode of the second reset transistor is coupled to a second initial signal line, and a second electrode of the second reset transistor is coupled to the fourth node. The second reset transistor is configured to transmit a second initial signal provided by the second initial signal line to the fourth node under control of a second reset signal provided by the second reset signal line.

In another aspect, a display apparatus is provided. The display apparatus includes the display substrate as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product to which the embodiments of the present disclosure relate.

FIG. 1 is a structural diagram of a display apparatus, in accordance with some embodiments of the present disclosure;

FIG. 2 is a structural diagram of a display substrate, in accordance with some embodiments of the present disclosure;

FIG. 3 is a structural diagram of a pixel circuit, in accordance with some embodiments of the present disclosure;

FIG. 4 is a structural diagram of another display substrate, in accordance with some embodiments of the present disclosure;

FIG. 5a is a structural diagram of another display apparatus, in accordance with some embodiments of the present disclosure;

FIG. 5b is a structural diagram of yet another display substrate, in accordance with some embodiments of the present disclosure;

FIG. 5c is a structural diagram of yet another display apparatus, in accordance with some embodiments of the present disclosure;

FIG. 5d is a structural diagram of yet another display apparatus, in accordance with some embodiments of the present disclosure;

FIG. 6a is a partial structural diagram of a display substrate in an implementation;

FIG. 6b is a graph of a driving current, a voltage at a fourth node and an enable signal versus time in an implementation;

FIG. 7a is a partial structural diagram of a display substrate, in accordance with some embodiments of the present disclosure;

FIG. 7b is a partial structural diagram of a display substrate, in accordance with some embodiments of the present disclosure;

FIG. 8a is a partial structural diagram of a driving transistor, in accordance with some embodiments of the present disclosure;

FIG. 8b is a partial structural diagram of another driving transistor, in accordance with some embodiments of the present disclosure;

FIG. 9 is a partial structural diagram of yet another driving transistor, in accordance with some embodiments of the present disclosure;

FIG. 10 is a partial structural diagram of yet another driving transistor, in accordance with some embodiments of the present disclosure;

FIG. 11a is a partial structural diagram of a compensation transistor, in accordance with some embodiments of the present disclosure;

FIG. 11b is a partial structural diagram of another compensation transistor, in accordance with some embodiments of the present disclosure;

FIG. 12 is a partial structural diagram of yet another compensation transistor, in accordance with some embodiments of the present disclosure;

FIG. 13 is a partial structural diagram of yet another compensation transistor, in accordance with some embodiments of the present disclosure;

FIG. 14a is a graph of a driving current, a voltage at a first node and an enable signal versus time in a first pixel circuit and a second pixel circuit in a display substrate, in accordance with some embodiments of the present disclosure;

FIG. 14b is a graph of a driving current, a voltage at a first node and an enable signal versus time in a first pixel circuit and a second pixel circuit in another display substrate, in accordance with some embodiments of the present disclosure;

FIG. 14c is a graph of a driving current, a voltage at a first node and an enable signal versus time in a first pixel circuit and a second pixel circuit in yet another display substrate, in accordance with some embodiments of the present disclosure;

FIG. 14d is a graph of a driving current, a voltage at a first node and an enable signal versus time in a first pixel circuit and a second pixel circuit in yet another display substrate, in accordance with some embodiments of the present disclosure;

FIG. 15a is a graph of current differences of second sub-pixels of different colors and a channel variation of a second pixel circuit in a display substrate, in accordance with some embodiments of the present disclosure;

FIG. 15b is a graph of current differences of second sub-pixels of different colors and a channel variation of a second pixel circuit in another display substrate, in accordance with some embodiments of the present disclosure;

FIG. 15c is a graph of current differences of second sub-pixels of different colors and a channel variation of a second pixel circuit in yet another display substrate, in accordance with some embodiments of the present disclosure;

FIG. 15d is a graph of current differences of second sub-pixels of different colors and a channel variation of a second pixel circuit in yet another display substrate, in accordance with some embodiments of the present disclosure; and

FIG. 16 is a diagram showing a calculation result of current differences of second sub-pixels of different colors in a case of a preset gray level being L255, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

In the description of some embodiments, the expressions “connected” and derivatives thereof may be used. For example, the term “connected” may be used in the description of some embodiments to indicate that two or more components are in direct physical or electrical contact with each other. The embodiments disclosed herein are not necessarily limited to the content herein.

The phrase “configured to” as used herein indicates an open and inclusive expression, which does not exclude apparatuses that are configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

It will be understood that when a layer or element is referred to as being on another layer or substrate, the layer or element may be directly on the another layer or substrate, or there may be intermediate layer(s) between the layer or element and the another layer or substrate.

Herein, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In each circuit structure (e.g., a pixel circuit) provided in embodiments of the present disclosure, the used transistors may be thin film transistors (TFTs), field effect transistors (metal oxide semiconductor, MOS) or other switching devices with same characteristics, and the embodiments of the present disclosure are described by taking the thin film transistors as an example.

In the circuit structure provided by the embodiments of the present disclosure, a first electrode of each transistor is one of source and drain, and a second electrode of each transistor is the other of the source and the drain. Since the source and the drain of the transistor may be symmetrical in structure, there may be no difference in structure between the source and the drain. That is, there may be no difference in structure between the first electrode and the second electrode of the transistor in the embodiments of the present disclosure. For example, in a case where the transistor is a P-type transistor, the first electrode of the transistor is a source, and the second electrode thereof is a drain. For example, in a case where the transistor is an N-type transistor, the first electrode of the transistor is a drain, and the second electrode thereof is a source.

In the circuit structure provided by the embodiments of the present disclosure, nodes such as a first node and a second node do not represent actual components, but represent junctions of related couplings in a circuit diagram. That is, these nodes are nodes equivalent to the junctions of the related couplings in the circuit diagram.

In the present disclosure, the P-type transistor may be turned on under control of a low-level signal, and the N-type transistor may be turned on under control of a high-level signal.

Hereinafter, the present disclosure will be described by taking an example where the transistors included in the pixel circuit are all P-type transistors.

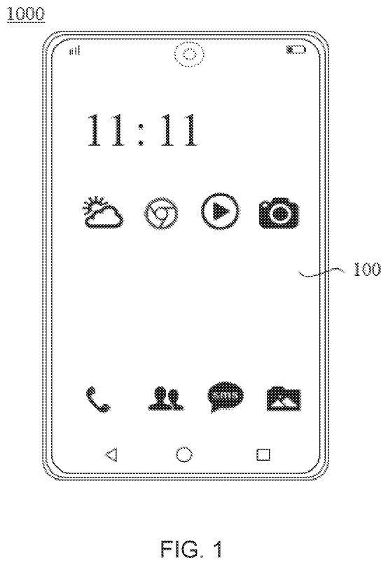

As shown in FIG. 1, some embodiments of the present disclosure provide a display apparatus 1000.

In some examples, the display apparatus 1000 may be any apparatus that displays images whether in motion (such as a video) or fixed (such as a still image), and regardless of text or image. More specifically, it is expected that the display apparatus in the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

For example, the display apparatus 1000 includes a frame, a display driver integrated circuit (IC), and other electronic components.

In some embodiments, the display apparatus 1000 further includes a display substrate 100.

In some example, the display substrate 100 includes a substrate, a pixel circuit layer and a light-emitting device layer that are stacked in sequence.

For example, the substrate may be a flexible substrate or a rigid substrate.

For example, in a case where the substrate is the flexible substrate, the material of the substrate may be dimethylsiloxane, polyimide (PI), polyethylene terephthalate (PET) and other high elastic materials. As another example, in a case where the substrate is the rigid substrate, the material of the substrate may be glass.

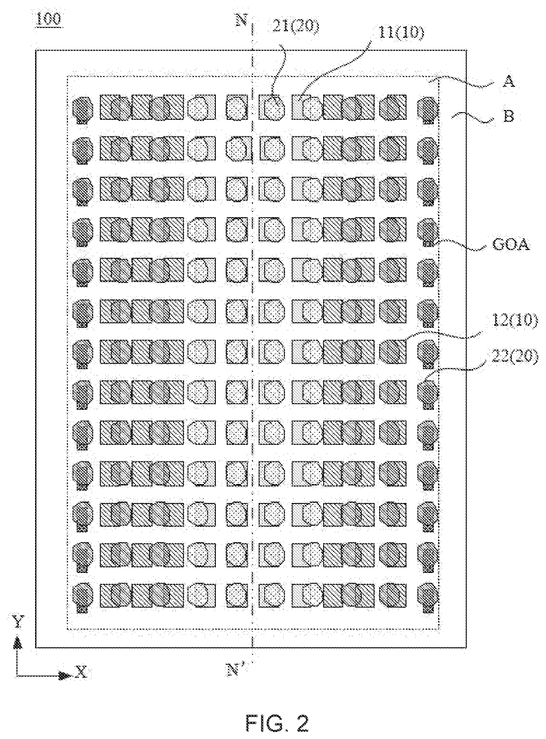

For example, the pixel circuit layer includes a plurality of pixel circuits 10, and the light-emitting device layer 20 includes a plurality of light-emitting devices 20. That is, as shown in FIG. 2, the display substrate 100 may include the plurality of pixel circuits 10 and the plurality of light-emitting devices 20.

For example, the pixel circuits 10 may be arranged in an array.

For example, the pixel circuit 10 may include a circuit composed of some transistors and some capacitors.

For example, the light-emitting devices 20 may be organic light emitting diode (OLED) light-emitting devices.

For example, the light-emitting device 20 may include a first electrode, a light-emitting functional layer and a second electrode that are sequentially stacked. The light-emitting functional layer may include a light-emitting layer. Optionally, the light-emitting functional layer may further include at least one of a hole injection layer, a hole transport layer, an electron transport layer and an electron injection layer.

For example, the first electrode may be one of an anode and a cathode, and the second electrode may be the other of the anode and the cathode, which is not limited in the present disclosure.

For convenience of description, the present disclosure will be described by taking an example where the first electrode is the anode and the second electrode is the cathode.

For example, the plurality of pixel circuits 10 and the plurality of light-emitting devices 20 may be arranged in one-to-one correspondence. As another example, in the present disclosure, a pixel circuit 10 may be coupled to multiple light-emitting devices 20; alternatively, multiple pixel circuits 10 may be coupled to a light-emitting device 20.

The present disclosure will schematically describe the structure of the display substrate 100 by taking an example of a single pixel circuit 10 being coupled to a single light-emitting device 20 below.

For example, in the display substrate 100, the circuit in the pixel circuit 10 may generate a driving signal (e.g., a driving current). Each light-emitting device 20 may emit light under driven of the driving signal generated by the pixel circuit 10 to which the light-emitting device 20 belongs. Lights emitted by the plurality of light-emitting devices 20 cooperate with each other, so that the display substrate 100 and the display apparatus 1000 realize the display function.

For example, the structure of the pixel circuit 10 may vary, and may be set according to actual needs. For example, the structure of the pixel circuit may include a “2T1C” structure, a “6T1C” structure, a “7T1C” structure, a “6T2C” structure, a “7T2C” structure or the like. Here, “T” represents a transistor, the number in front of “T” represents the number of the transistors, “C” represents a storage capacitor, and the number in front of “C” represents the number of the storage capacitor(s).

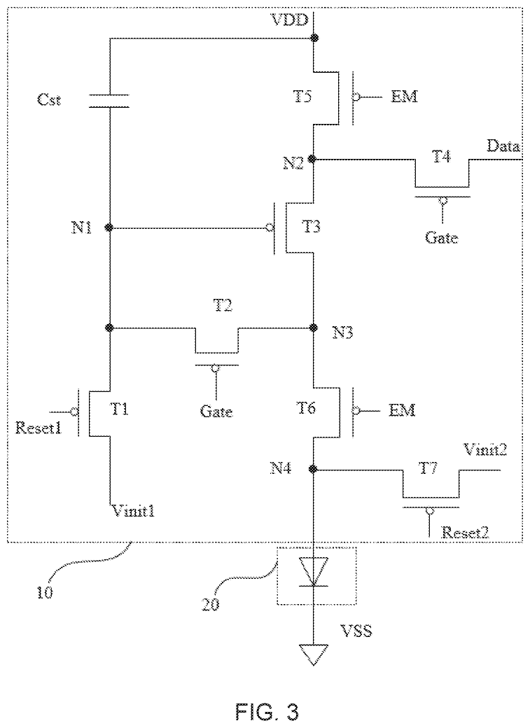

The structure and operation process of the pixel circuit 10 will be schematically described below with reference to FIG. 3 by taking an example where the structure of the pixel circuit 10 is the “7T1C” structure. It will be noted that, seven transistors and one storage capacitor that are included in the pixel circuit 10 may alternatively have other coupling relationships, and are not limited to the coupling relationships shown in this example.

It can be understood that during the operation of the pixel circuit 10, a variety of signal lines are required to provide corresponding electrical signals. Therefore, for example, the display substrate 100 further includes a first initial signal line Vinit1 for transmitting a first initial signal, a second initial signal line Vinit2 for transmitting a second initial signal, a scanning signal line Gate for transmitting a scanning signal, a first reset signal line Reset1 for transmitting a first reset signal, a second reset signal line Reset2 for transmitting a second reset signal, an enable signal line EM for transmitting an enable signal, a data line Data for transmitting a data signal, a voltage signal line VDD for transmitting a first voltage signal, and a common voltage signal line VSS for transmitting a common voltage signal.

In some examples, as shown in FIG. 3, the pixel circuit 10 includes a first reset transistor T1, a compensation transistor T2, a driving transistor T3, a switch transistor T4, a first light emission control transistor T5, a second light emission control transistor T6, a second reset transistor T7 and a storage capacitor Cst.

For example, a gate of the first reset transistor T1 is coupled to the first reset signal line Reset1, a first electrode of the first reset transistor T1 is coupled to the first initial signal line Vinit1, and a second electrode of the first reset transistor T1 is coupled to a first node N1. The first reset transistor T1 is configured to transmit the first initial signal to the first node N1 under control of the first initial signal.

For example, in a case where a level of the first initial signal is an operating level, the first reset transistor T1 is turned on to transmit the first initial signal from the first initial signal line Vinit1 to the first node N1, so as to reset the first node N1.

It will be noted that the “operating level” in the present disclosure refers to a level that enables a transistor to be turned on. In a case where the transistor is an N-type transistor, the “operating level” is a high level. In a case where the transistor is a P-type transistor, the “operating level” is a low level. The following embodiments have the same meaning as the above, and details will not be repeated.

For example, a first electrode plate of the storage capacitor Cst is coupled to the first voltage signal line VDD, and a second electrode plate of the storage capacitor Cst is coupled to the first node N1.

For example, a gate of the switch transistor T4 is coupled to the scanning signal line Gate, a first electrode of the switch transistor T4 is coupled to the data signal line Data, and a second electrode of the switch transistor T4 is coupled to a second node N2. The switch transistor T4 is configured to transmit the data signal to the second node N2 under control of the scanning signal.

For example, in a case where a level of the scan signal is an operating level, the switch transistor T4 is turned on to transmit the data signal from the data signal line Data to the second node N2.

For example, a gate of the driving transistor T3 is coupled to the first node N1, a first electrode of the driving transistor T3 is coupled to the second node N2, and a second electrode of the driving transistor T3 is coupled to a third node N3. The driving transistor T3 is configured to transmit an electrical signal at the second node N2 to the third node N3 under control of an electrical signal at the first node N1.

For example, in a case where a level of the electrical signal at the first node N1 is an operating level, the driving transistor T3 is turned on to transmit the electrical signal (e.g., the data signal) at the second node N2 to the third node N3.

For example, a gate of the compensation transistor T2 is coupled to the scanning signal line Gate, a first electrode of the compensation transistor T2 is coupled to the third node N3, and a second electrode of the compensation transistor T2 is coupled to the first node N1. The compensation transistor T2 is configured to transmit the electrical signal at the third node N3 to the first node N1 under control of the scanning signal, so as to compensate the threshold voltage of the driving transistor T3 and charge the storage capacitor Cst coupled to the first node N1.

For example, in a case where a level of the scanning signal is an operating level, the compensation transistor T2 is turned on to transmit the electrical signal (e.g., the data signal) at the third node N3 to the first node N1.

For example, a gate of the second reset transistor T7 is coupled to the second reset signal line Reset2, a first electrode of the second reset transistor T7 is coupled to the second initial signal line Vinit2, and a second electrode of the second reset transistor T7 is coupled to a fourth node N4. The second reset transistor T7 is configured to transmit the second initial signal to the fourth node N4 under control of the second initial signal.

For example, in a case where a level of the second initial signal is an operating level, the second reset transistor T7 is turned on to transmit the second initial signal from the second initial signal line Vinit2 to the fourth node N4, so as to reset the fourth node N4.

For example, a gate of the first light emission control transistor T5 is coupled to the enable signal line EM, a first electrode of the first light emission control transistor T5 is coupled to the first voltage signal line VDD, and a second electrode of the first light emission control transistor T5 is coupled to the second node N2. The first light emission control transistor T5 is configured to transmit the first voltage signal to the second node N2 under control of the enable signal.

For example, in a case where a level of the enable signal is an operating level, the first light emission control transistor T5 is turned on to transmit the first voltage signal from the first voltage signal line VDD to the second node N2.

For example, a gate of the second light emission control transistor T6 is coupled to the enable signal line EM, a first electrode of the second light emission control transistor T6 is coupled to the third node N3, and a second electrode of the second light emission control transistor T6 is coupled to the fourth node N4. The second light emission control transistor T6 is configured to transmit the electrical signal at the third node N3 to the fourth node N4 under control of the enable signal.

For example, in a case where a level of the enable signal is an operating level, the second light emission control transistor T6 is turned on to transmit the electrical signal (e.g., a driving signal) at the third node N3 to the fourth node N4.

For example, an end of the light-emitting device 20 is coupled to the fourth node N4, and the other end of the light-emitting device 20 is coupled to the common voltage signal line VSS. The light-emitting device 20 emits light due to action of the electrical signal at the fourth node N4 and the common voltage signal provided by the common voltage signal line VSS.

For example, the operation process of the pixel circuit 10 includes a reset phase, a data writing and compensation phase, and a light-emitting phase that are performed in sequence.

For example, in the reset phase, the first reset transistor T1 is turned on under the control of the reset signal to transmit the first initial signal to the first node N1, so as to reset the first node N1. The first node N1 is coupled to the storage capacitor Cst, the gate of the driving transistor T3 and the second electrode of the compensation transistor T2. Therefore, when the first node N1 is reset, the storage capacitor Cst, the gate of the driving transistor T3 and the second electrode of the compensation transistor T2 may be reset. The driving transistor T3 may be turned on under control of the first initial signal.

For example, in the data writing and compensation phase, the switch transistor T4 and the compensation transistor T2 are both turned on under the control of the scanning signal. The switch transistor T4 transmits the data signal to the second node N2, and the driving transistor T3 is turned on under control of the first node N1 to transmit the data signal at the second node N2 to the third node N3. The compensation transistor T2 transmits the data signal at the third node N3 to the first node N1, so as to charge the driving transistor T3 until the driving transistor T3 is in an off state, so that the compensation of the threshold voltage of the driving transistor T3 is achieved. The second reset transistor T7 transmits the second initial signal to the fourth node N4. The fourth node N4 is coupled to the first electrode of the light-emitting device 20. Therefore, when the fourth node N4 is reset, the first electrode of the light-emitting device 20 may be reset.

For example, in the light-emitting phase, the first light emission control transistor T5 and the second light emission control transistor T6 are both turned on under the control of the enable signal. The first light emission control transistor T5 transmits the first voltage signal to the second node N2, the driving transistor T3 transmits the electrical signal at the second node N2 to the third node N3, and the second light emission control transistor T6 transmits a voltage signal at the third node N3 to the fourth node N4. The light-emitting device 20 emits light due to the action of the electrical signal at the fourth node N4 and the common voltage signal from the common voltage line VSS.

It will be noted that in a case where a preset grayscale is a low grayscale, in the light-emitting phase, the fourth node N4 of the pixel circuit 10 needs to be pre-charged for a certain time to reach a preset light-emitting voltage, and the light-emitting device 20 can emit light under action of the preset light-emitting voltage and common voltage signal.

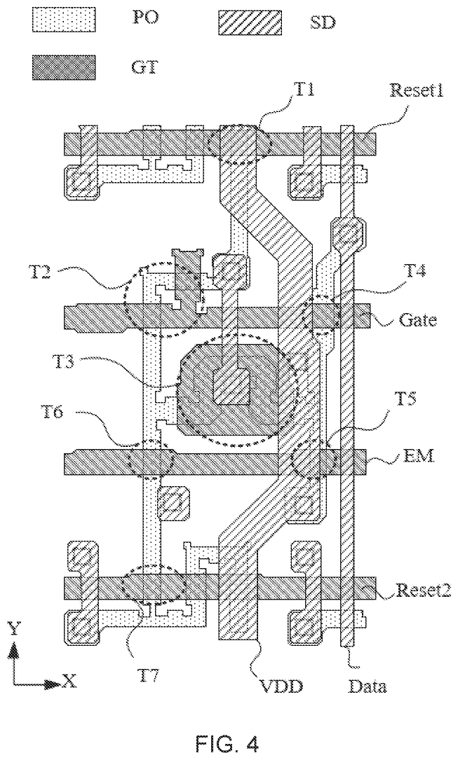

In some embodiments, as shown in FIG. 4, the pixel circuit layer includes a semiconductor layer PO, a gate conductive layer GT and a source-drain conductive layer SD that are sequentially disposed on a side of the substrate.

It will be noted that only a partial pattern of the semiconductor layer PO, a partial pattern of the gate conductive layer GT, and a partial pattern of the source-drain conductive layer SD are illustrated in FIG. 4.

For example, the source-drain conductive layer SD may be a single film layer disposed on a side of the gate conductive layer GT, or two film layers disposed on the side of the gate conductive layer GT. The specific selection may be made according to actual needs, and is not limited in the present disclosure.

In some examples, the material of the semiconductor layer PO may include amorphous silicon, monocrystalline silicon, polycrystalline silicon and other materials, and may also include metal oxide semiconductor materials such as indium gallium zinc oxide (IGZO).

In some examples, the materials of the gate conductive layer GT and the source-drain conductive layer SD are both conductive materials. For example, the conductive material may be a metal material, such as aluminum (Al), silver (Ag), copper (Cu) and chromium (Cr).

For example, a first insulating layer is provided between the semiconductor layer PO and the gate conductive layer GT. The first insulating layer is used to isolate the semiconductor layer PO and the gate conductive layer GT to avoid short circuit. A second insulating layer is provided between the gate conductive layer GT and the source-drain conductive layer SD. The second insulating layer is used to isolate the gate conductive layer GT and the source-drain conductive layer SD to avoid short circuit.

For example, the materials of the first insulating layer and the second insulating layer may be silicon oxide, silicon nitride, silicon oxynitride, or the like.

It will be noted that an orthographic projection of the semiconductor layer PO on the substrate is overlapped with an orthographic projection of the gate conductive layer GT on the substrate. After the gate conductive layer GT is formed on a side of the semiconductor layer PO away from the substrate, the gate conductive layer GT may be used as a mask to perform doping treatment on the semiconductor layer PO. As a result, portions of the semiconductor layer PO not covered by the gate conductive layer GT become conductors, and the conductors may constitute first electrodes or second electrodes of some transistors; and portions of the semiconductor layer PO covered by the gate conductive layer GT become channel portions of some transistors. Portions of the gate conductive layer GT overlapped with the semiconductor layer PO constitute gate patterns of some transistors, and the gate patterns become gates of the transistors. The channel portion has a channel length and a channel width. For example, the channel length of the channel portion refers to a dimension of a portion of the channel portion located between the first electrode and the second electrode of the transistor in a direction of a connecting line of the first electrode and the second electrode of the transistor, and the channel width of the channel portion refers to a dimension of the channel portion in a direction perpendicular to the connecting line of the first electrode and the second electrode of the transistor.

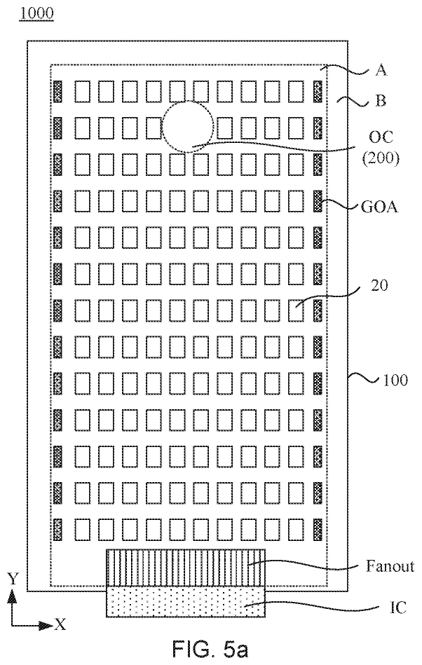

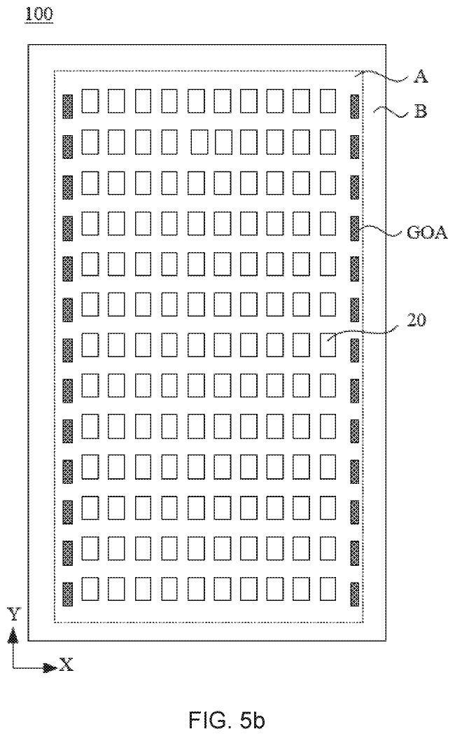

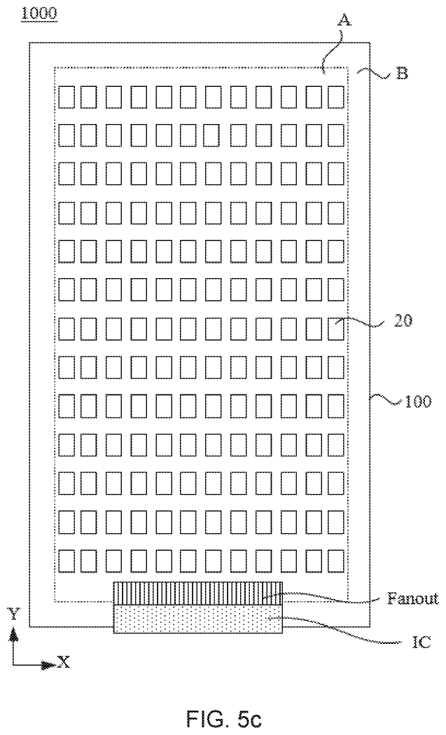

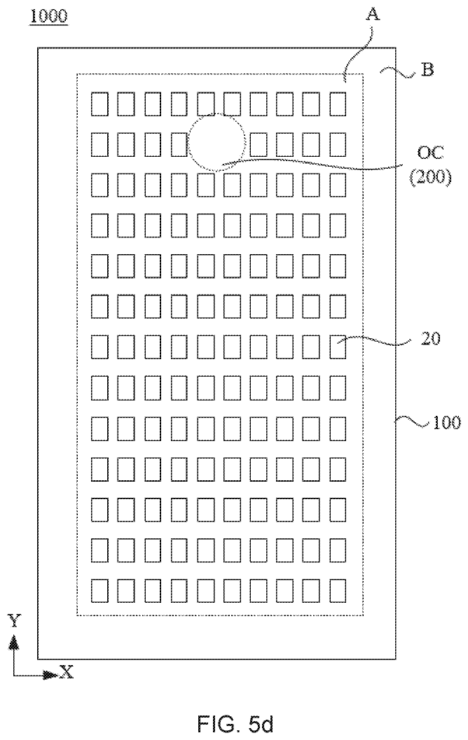

In some examples, as shown in FIG. 5a, the display substrate 100 has a display region A and a frame region B.

For example, the display region A refers to a region of the display substrate 100 used for display an image.

For example, the shape of the display region A may vary, and may be provided according to actual needs.

For example, the shape of the display region A may be a rectangle, a quasi-rectangle, a circle, an oval, or the like. The quasi-rectangle is a rectangle in a non-strict sense, and four inner corners thereof may be, for example, rounded corners, or a certain side thereof may not be, for example, a straight line.

For convenience of description, the present disclosure will be described by taking an example where the shape of the display region A is the rectangle.

For example, the plurality of pixel circuits 10 and the plurality of light-emitting devices 20 are all disposed in the display region A.

For example, the light-emitting devices 20 may be evenly distributed in the display region A, thereby ensuring uniformity of the image displayed by the display substrate 100 and the display apparatus 1000 to a certain extent.

For example, the frame region B may be provided around the display region A.

There are a variety of arrangements for the part of the display substrate 100 located in the display region A. For example, at least one of shift register(s) GOA, a fan-out unit Fanout and optical elements (e.g., a camera, an infrared sensor or a fingerprint sensor) may be provided in the display region A. The specific provision may be made according to actual needs, and is not limited in the present disclosure.

In some examples, as shown in FIGS. 5a and 5b, the display substrate 100 further includes at least one shift register GOA located in the display region A. The at least one shift register GOA is located between the substrate and the light-emitting device layer, and there is no overlap between an orthographic projection of the at least one shift register GOA on the substrate and an orthographic projection of the pixel circuit layer on the substrate.

For example, the display region A is provided with one or more shift register circuits GOA therein.

For example, the shift register GOA may be located at a position of the display substrate 100 proximate to a boundary line of the display region A and the frame region B.

For example, as shown in FIG. 5b, a plurality of shift registers GOA may be arranged in a second direction Y on both sides of the display region A in a first direction X.

For example, the above “no overlap” means that the at least one shift register GOA and the pixel circuits 10 in the pixel circuit layer have no overlap parts in a thickness direction of the display substrate 100.

The at least one shift register GOA and the pixel circuit layer are both located between the substrate and the light-emitting device layer, and there is no overlap between orthographic projections of the two on the substrate. Therefore, the at least one shift register GOA and the pixel circuits 10 in pixel circuit layer may be formed in the same manufacturing process.

For example, the shift register GOA may include a first shift register, and the first shift register may be electrically connected to the scanning signal line Gate and provide the scanning signal for pixel circuits 10 electrically connected to the scanning signal line Gate. The shift register circuit GOA may also include a second shift register, and the second shift register may be electrically connected to the enable signal line EM and provide the enable signal for pixel circuits 10 electrically connected to the enable signal line EM.

With the above provision manner, the shift register(s) GOA are provided in the display region A, so that the number of the shift register(s) GOA provided in the frame region B may be reduced, thereby reducing an area of the frame region B in the display substrate 100 and increasing an area ratio of the display region A in the display substrate 100, and being further beneficial to realizing a narrow frame design of the display substrate 100 and the display apparatus 1000.

For example, since the at least one shift register GOA is disposed between the substrate and the light-emitting device layer, there is no overlap between the orthographic projection of the shift register GOA on the substrate and the orthographic projection of the pixel circuit layer on the substrate, and an area of the display region A is fixed, an area occupied by the at least one shift register circuit GOA will cause an area occupied by the plurality of pixel circuits 10 in the pixel circuit layer to be reduced. However, an area occupied by the plurality of light-emitting devices 20, driven by the plurality of pixel circuits 10, in the light-emitting device layer does not decrease, so that misalignment may occur between part of pixel circuits 10 and light-emitting devices 20 driven thereby. That is, in the display substrate 100, this part of pixel circuits 10 and the light-emitting devices 20 driven thereby are not provided directly opposite to each other, or this part of pixel circuits 10 and the light-emitting devices 20 driven thereby have relatively long distances therebetween.

For example, the shift register(s) GOA may alternatively be provided in the frame region B.

In some examples, as shown in FIGS. 5a and 5c, the display substrate 100 further includes a fan-out unit Fanout located in the display region A. The fan-out unit Fanout is located between the substrate and the light-emitting device layer, and there is no overlap between an orthographic projection of the fan-out unit Fanout on the substrate and the orthographic projection of the pixel circuit layer on the substrate.

For example, the above “no overlap” means that the fan-out unit Fanout and the pixel circuits 10 in the pixel circuit layer have no overlap parts in the thickness direction of the display substrate 100.

For example, the fan-out unit Fanout may be located in a region of the display region A proximate to the display driver IC.

The fan-out unit Fanout and the pixel circuit layer are both located between the substrate and the light-emitting device layer, and there is no overlap between orthographic projections of the two on the substrate. Therefore, the fan-out unit Fanout and the pixel circuits 10 in the pixel circuit layer may be formed in the same manufacturing process.

For example, the fan-out unit Fanout may be coupled with the display driver IC of the display apparatus 1000.

For example, the fan-out unit Fanout may include data fan-out lines, first voltage fan-out lines, and the like.

For example, the display driver IC may provide data signals for the data fan-out lines of the fan-out unit Fanout and provide first voltage signals for the first voltage fan-out lines of the fan-out unit Fanout. The data fan-out line may be coupled to a data signal line Data and then transmit a data signal to pixel circuits 10. The first voltage fan-out line may be coupled to a first voltage signal line VDD and then transmit a first voltage signal to pixel circuits 10.

With the above provision manner, the fan-out unit Fanout is provided in the display region A, so that an area of the frame region B occupied by the fan-out unit Fanout may be saved, thereby reducing an area of the frame region B in the display substrate 100 and increasing an area ratio of the display region A in the display substrate 100, and being further beneficial to realizing a narrow frame design of the display substrate 100 and the display apparatus 1000.

For example, since the fan-out unit Fanout is located between the substrate and the light-emitting device layer, there is no overlap between the orthographic projection of the fan-out unit Fanout on the substrate and the orthographic projection of the pixel circuit layer on the substrate, and the area of the display region A is fixed, an area occupied by the fan-out unit Fanout will cause the area occupied by the plurality of pixel circuits 10 in the pixel circuit layer to be reduced. However, the area occupied by the plurality of light-emitting devices 20 in the light-emitting device layer does not decrease, so that misalignment may occur between part of pixel circuits 10 and light-emitting devices 20 driven thereby. That is, in the display substrate 100, this part of pixel circuits 10 and the light-emitting devices 20 driven thereby are not provided directly opposite to each other, or this part of pixel circuits 10 and the light-emitting devices 20 driven thereby have relatively long distances therebetween.

For example, the fan-out unit Fanout may alternatively be located in the frame region B of the display substrate 100.

In some examples, as shown in FIGS. 5a and 5d, the display substrate 100 further includes an optical element region OC and an optical element 200.

For example, an orthographic projection of the optical element 200 on a plane where the display substrate 100 is located is located within the optical element region OC of the display substrate 100.

For example, only a small number of pixel circuits 10 or no pixel circuits 10 may be provided in the optical element region OC. In this way, light transmittance of a region of the display substrate 100 located in the optical element region OC is greater than light transmittance of a region of the display substrate 100 located in the display region A.

For example, the optical element region OC may also be used to display an image.

For example, the optical element 200 may be a camera, a fingerprint recognition sensor, an infrared sensor, or the like.

With the above provision manner, it may be ensured that enough light may reach the optical element 200 through the optical device region OC, so that the optical element 200 can collect the light, thereby ensuring normal work of the optical element 200 and improving a ratio of an area of a region (e.g., the above display region A) for displaying the image to an area of the display substrate 100, and being further beneficial to realizing a full-screen design of the display substrate 100 and the display apparatus 1000.

For example, in order to ensure the uniformity of the display effect of the display substrate 100, density of light-emitting devices 20 in the optical element region OC is the same as density of all the light-emitting devices 20 in the display region a. In order to ensure that the optical element 200 can collect enough light, only a small number of pixel circuits 10 or no pixel circuits 10 may be provided in a region of the display substrate 100 located in the optical element region OC. Therefore, the number of light-emitting devices 20 located in the optical element region OC is greater than the number of pixel circuits 10 located in the optical element region OC, so that part of pixel circuits 10 corresponding to part of light-emitting devices 20 in the optical element region OC are provided in a region of the display region A except the optical element region OC, and thus misalignment may occur between this part of pixel circuits 10 and the light-emitting devices 20 driven thereby. That is, in the display substrate 100, this part of pixel circuits 10 and the light-emitting devices 20 driven thereby are not provided directly opposite to each other, or this part of pixel circuits 10 and the light-emitting devices 20 driven thereby have relatively long distances therebetween.

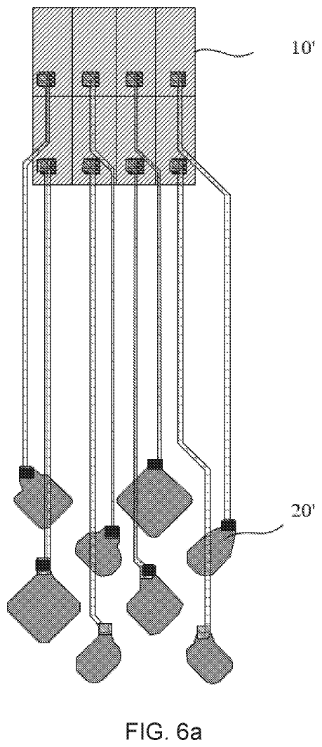

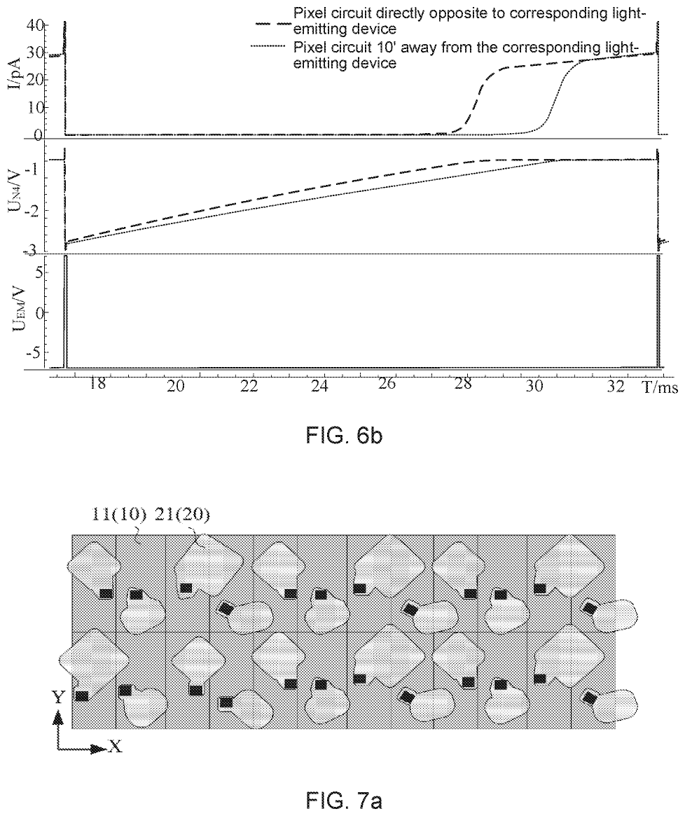

In an implementation, if the shift register or the fan-out unit of the display substrate is provided in the display region, or only a small number of pixel circuits or no pixel circuits 10 are provided in the optical element region of the display substrate, as shown in FIG. 6a, part of pixel circuits 10′ and corresponding light-emitting devices 20′ are not provided directly opposite to each other, or the part of pixel circuits 10′ and the corresponding light-emitting devices 20′ have relatively long distances therebetween. Therefore, as shown in FIG. 6b, in the light-emitting phase of the pixel circuit, loads of the fourth nodes N4 in the above part of pixel circuits 10′ are relatively large (relative to a case that the pixel circuits and the light-emitting devices are provided directly opposite to each other), and the time for pre-charging the four-nodes N4 to the preset light-emitting voltages are relatively long, so that the driving currents for driving the light-emitting devices 20′ to emit light in this part of the pixel circuits 10′ are relatively small. As a result, this part of light-emitting devices 20′ are turned on slowly or luminous brightness of this part of light-emitting devices 20′ is low, thereby causing the display substrate and the display apparatus to be prone to uneven luminescence as a whole, which is particularly obvious in a low grayscale case.

In light of this, some embodiments of the present disclosure provide a display substrate 100. As shown in FIG. 2, in the display substrate 100, a plurality of pixel circuits 10 include a plurality of first pixel circuits 11 and a plurality of second pixel circuits 12, and a plurality of light-emitting devices 20 include a plurality of first light-emitting devices 21 and a plurality of second light-emitting devices 22.

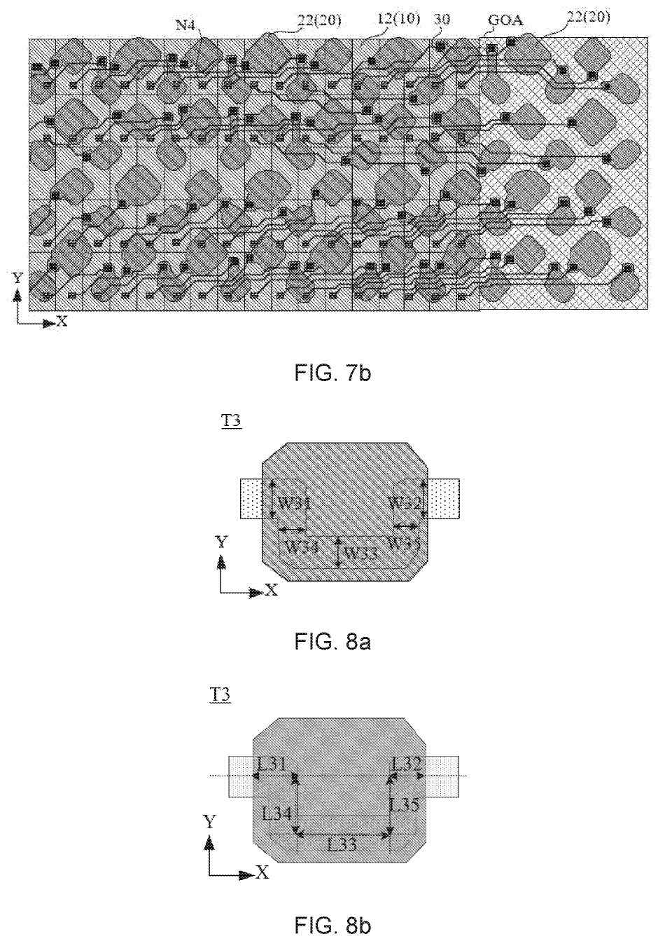

In some examples, as shown in FIGS. 2 and 7a, the first pixel circuits 11 are respectively coupled to the first light-emitting devices 21, and the first pixel circuit 11 is disposed at least partially directly opposite to the first light-emitting device 21.

For example, the above “at least partially directly opposite” refers to an orthogonal projection of the first pixel circuit 11 on a plane where the display substrate 100 is located and an orthogonal projection of the first light-emitting device 21 driven thereby on the plane where the display substrate 100 is located coincide partially or completely.

The above provision manner may make a load of a fourth node N4 in the first pixel circuit 11 small, and thus make charging of the fourth node N4 completed in a short time in the light-emitting phase. As a result, the fourth node N4 may reach a preset voltage quickly, so that the first light-emitting device 21 may be turned on quickly, and can emit light consistent with a preset grayscale at the preset voltage, thereby alleviating or even avoiding the uneven brightness of the display substrate 100 and the display apparatus 1000.

It will be noted that FIG. 2 only shows the relative positional relationship of the first pixel circuits 11, the second pixel circuits 12, the first light-emitting devices 21, the second light-emitting devices 22 and the shift registers GOA in the display substrate 100, and the connection relationship between the above structures is not illustrated.

In some examples, as shown in FIGS. 2 and 7b, the second pixel circuits 12 are respectively coupled to the second light-emitting devices 22, and an orthogonal projection of the second pixel circuit 12 on the plane where the display substrate 100 is located is not overlapped with an orthogonal projection of the second light-emitting device 22 driven thereby on the plane where the display substrate 100 is located.

For example, in a thickness direction of the display substrate 100, the second pixel circuit 12 and the second light-emitting device 22 driven thereby are misalignment designed, and there is no direct opposite parts between the two. There is no coinciding parts between an border line of an orthographic projection of the second pixel circuit 12 on the plane where the display substrate 100 is located and an border line of an orthographic projection of the second light-emitting device 22 driven thereby on the plane where the display substrate 100 is located.

For example, in a case where the display region A of the display substrate 100 includes shift register(s) GOA and/or a fan-out unit Fanout that are located between the substrate and the pixel circuit layer, and/or the display region A includes an optical element region OC, the second pixel circuits 12 are generally located in a region proximate to the shift register GOA and/or the fan-out unit Fanout and/or the optical element region OC. In a case where the display substrate 100 shown in FIG. 2 includes shift registers GOA located in the display region A, the second pixel circuits 12 are located in regions each proximate to a boundary line between the frame region B and the display region A.

The arrangement of the driving transistor T3 and the compensation transistor T2 in the pixel circuit 10 may vary. The specific provision may be made according to actual needs, and is not limited in the present disclosure.

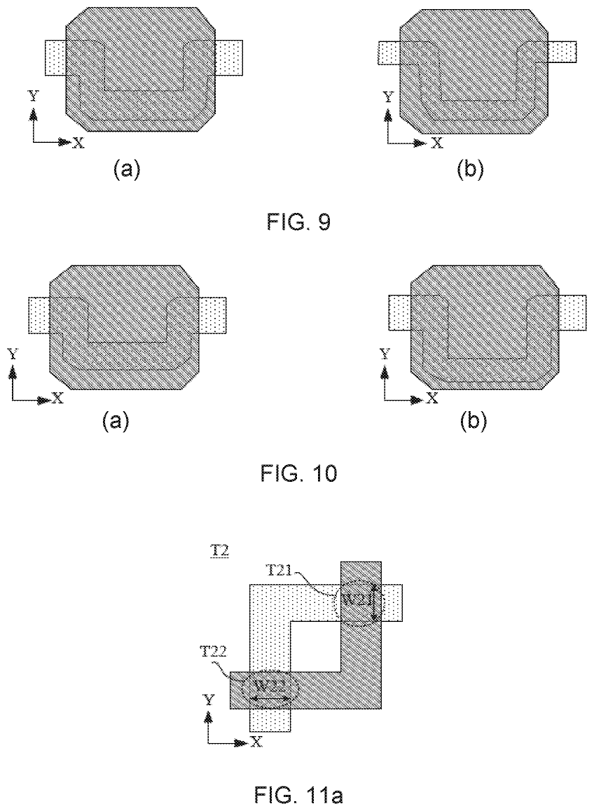

In some examples, as shown in FIG. 9, a width-to-length ratio of a channel of a driving transistor T3 in the first pixel circuit 11 is greater than a width-to-length ratio of a channel of a driving transistor T3 in the second pixel circuit 12.

A partial structural diagram of the driving transistor T3 in the first pixel circuit 11 is shown in (a) of FIG. 9, and a partial structural diagram of the driving transistor T3 in the second pixel circuit 12 is shown in (b) of FIG. 9.

For example, the width-to-length ratio of the channel of the driving transistor T3 refers to a ratio of a channel width of the channel portion of the driving transistor T3 to a length of the channel portion.

It will be noted that a width-to-length ratio of a transistor is related to an on-state current when the transistor is turned on. The greater the width-to-length ratio of the transistor, the greater the corresponding on-state current.

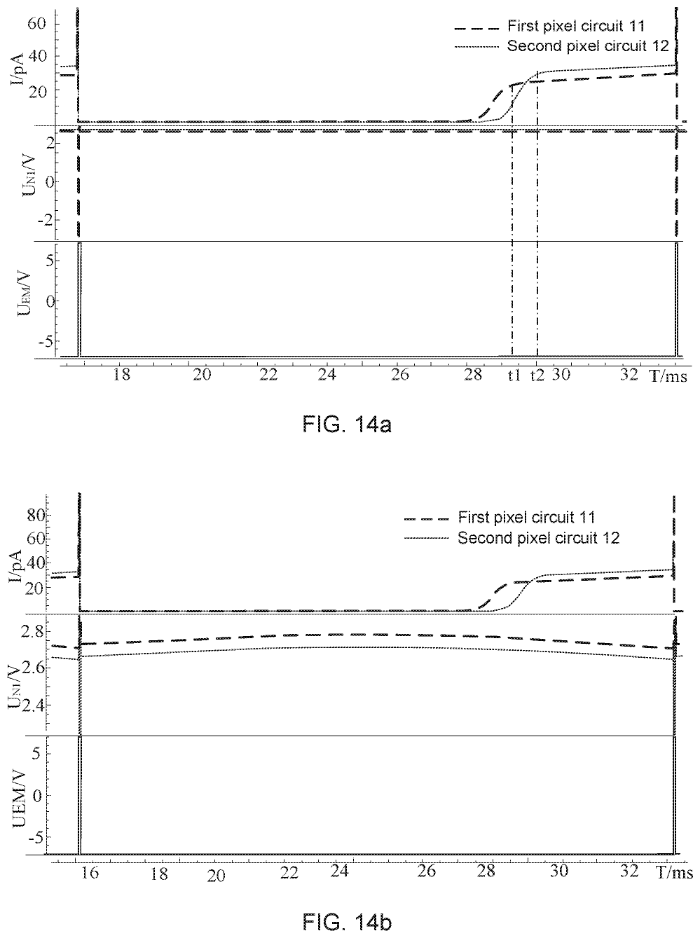

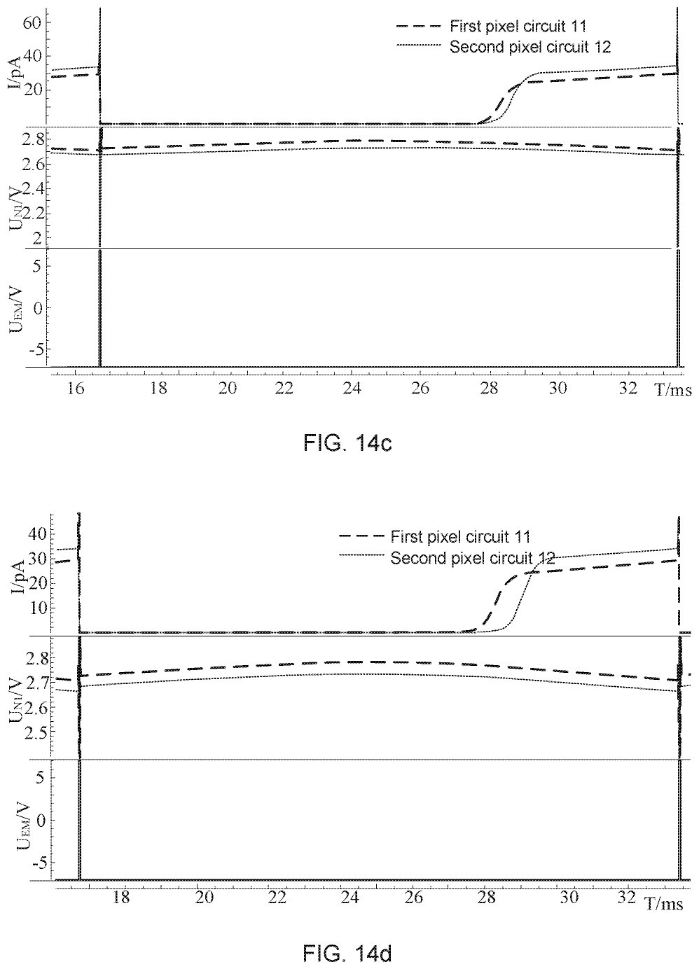

With the above provision manner, since the width-to-length ratio of the channel of the driving transistor T3 in the second pixel circuit 12 is less than the width-to-length ratio of the channel of the driving transistor T3 in the first pixel circuit 11, the on-state current of the driving transistor T3 in the second pixel circuit 12 is smaller than the on-state current of the driving transistor T3 in the first pixel circuit 11. Therefore, in the data writing and compensation phase of the pixel circuit, charging of the first node N1 by the driving transistor T3 through the compensation transistor T2 in the second pixel circuit 12 is insufficient. After the charging is completed, a voltage at the first node N1 in the second pixel circuit 12 is lower than a voltage at the first node N1 in the first pixel circuit 11. In this way, in a case where the preset grayscale is a low grayscale, in the light-emitting phase of the second pixel circuit 12, the driving transistor T3 controlled by the first node N1 is more fully turned on, resulting in a relatively large starting value of the driving current passing through the driving transistor T3 in the second pixel circuit 12 (the starting value of the driving current here refers to a magnitude of the driving current when the value of the driving current tends to be stable, such as the magnitude of the driving current corresponding to t1 or t2 in FIG. 14a of the present disclosure). Thus, the overall decrease of the value of the driving current due to a long time for pre-charging the fourth node N4 may be compensated. Therefore, the driving current passing through the driving transistor T3 in the second pixel circuit 12 (the driving current here refers to an average value of the driving currents in a light-emitting phase) increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, as shown in FIG. 12, a channel capacitance of a compensation transistor T2 in the first pixel circuit 11 is larger than a channel capacitance of a compensation transistor T2 in the second pixel circuit 12.

For example, the channel capacitance of the compensation transistor T2 refers to a capacitance of a capacitor composed by the channel portion of the compensation transistor T2 and the gate of the compensation transistor T2. The gate of the compensation transistor T2 and the scanning signal line Gate have an integrated structure.

It will be noted that since the channel portion is a portion of the semiconductor layer directly opposite to the gate, a size of a channel area is a size of the channel capacitor of the channel portion. Therefore, the larger the channel area, the larger the capacitance of the channel capacitor of the channel portion.

With the above provision manner, in a case where the compensation transistor T2 is turned off, a level of the scanning signal transmitted by the scanning signal line Gate changes from a low level to a high level. That is to say, a voltage of the gate of the compensation transistor T2 increases, and thus a voltage of the second electrode of the compensation transistor T2 connected to the first node N1 will increase accordingly. Since the channel capacitance of the compensation transistor T2 in the second pixel circuit 12 is smaller than the channel capacitance of the compensation transistor T2 in the first pixel circuit 11, in a case where the voltage of the gate of the compensation transistor T2 increases, an increased amplitude of the voltage of the channel portion of the compensation transistor T2 in the second pixel circuit 12 is smaller than an increased amplitude of the voltage of the channel portion of the compensation transistor T2 in the first pixel circuit 11. Since the channel portion of the compensation transistor T2 is connected to the first node N1 through the second electrode of the compensation transistor T2, that is, an increased amplitude of the voltage at the first node N1 in the second pixel circuit 12 is smaller than an increased amplitude of the voltage at the first node N1 in the first pixel circuit 11, so that the voltage at the first node N1 in the second pixel circuit 12 is less affected by the channel capacitor of the corresponding compensation transistor T2, and the voltage at the first node N1 in the second pixel circuit 12 is lower than the voltage at the first node N1 in the first pixel circuit 11. Thus, in the light-emitting phase, the driving transistor T3 in the second pixel circuit 12 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated. Therefore, the driving current passing through the driving transistor T3 in the second pixel circuit 12 (the driving current here refers to an average value of the driving currents in a light-emitting phase) increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, the width-to-length ratio of the channel of the driving transistor T3 in the first pixel circuit 11 is greater than the width-to-length ratio of the channel of the driving transistor T3 in the second pixel circuit 12, and the channel capacitance of the compensation transistor T2 in the first pixel circuit 11 is larger than the channel capacitance of the compensation transistor T2 in the second pixel circuit 12.

With the above provision manner, since the width-to-length ratio of the channel of the driving transistor T3 in the second pixel circuit 12 is relatively small, the on-state current of the driving transistor T3 in the second pixel circuit 12 is small. Therefore, in the data writing and compensation phase of the pixel circuit, charging of the first node N1 by the driving transistor T3 through the compensation transistor T2 is insufficient. After the charging is completed, a voltage at the first node N1 in the second pixel circuit 12 is less than a preset voltage value. Moreover, in a case where the compensation transistor T2 is turned off, the scanning signal transmitted by the scanning signal line Gate changes from a low level to a high level. That is to say, a voltage of the gate of the compensation transistor T2 increases, and thus a voltage at the first node N1 connected to the second electrode of the compensation transistor T2 will increase accordingly. Since the channel capacitance of the compensation transistor T2 in the second pixel circuit 12 is relatively small, in a case where the voltage of the gate of the compensation transistor T2 increases, an increased amplitude of the voltage of the second electrode of the compensation transistor T2 is relatively small, so that the voltage at the first node N1 is less affected by the channel capacitor, an increased amplitude of the voltage at the first node N1 in the second pixel circuit 12 is relatively small, and the voltage at the first node N1 in the second pixel circuit 12 is relatively low. Further, in the light-emitting phase, the driving transistor T3 controlled by the first node N1 is more fully turned on, resulting in a relatively large starting value of the driving current passing through the driving transistor T3. Thus, the overall decrease of the value of the driving current due to a long time for pre-charging the fourth node N4 may be compensated, so that the driving current passing through the driving transistor T3 in the second pixel circuit 12 (the driving current here refers to an average value of the driving currents in a light-emitting phase) increases, and the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

It will be noted that in a case where the width-to-length ratio of the channel of the driving transistor T3 in the first pixel circuit 11 is greater than the width-to-length ratio of the channel of the driving transistor T3 in the second pixel circuit 12, the arrangement of the driving transistor T3 in the first pixel circuit 11 and the driving transistor T3 in the second pixel circuit 12 may vary. The specific provision may be made according to actual needs, and is not limited in the present disclosure.

In some embodiments, as shown in FIG. 9, a channel width of the driving transistor T3 in the first pixel circuit 11 is larger than a channel width of the driving transistor T3 in the second pixel circuit 12.

A partial structural diagram of the driving transistor T3 in the first pixel circuit 11 is shown in (a) of FIG. 9, and a partial structural diagram of the driving transistor T3 in the second pixel circuit 12 is shown in (b) of FIG. 9.

In some examples, as shown in FIGS. 4 and 9, the channel of the driving transistor T3 is in a shape of a broken line, and the channel with the broken line shape includes portions extending in the first direction X and portions extending in the second direction Y. As shown in FIG. 8a, the channel width of the driving transistor T3 is an average value of dimensions of widths W31, W32 and W33 of the portions of the channel extending in the first direction X and dimensions of widths W34 and W35 of the portions of the channel extending in the second direction Y (i.e., W3=(W31+W32+W33+W34 +W35)/5).

With the above provision manner, the channel width of the driving transistor T3 in the first pixel circuit 11 is provided to be larger than the channel width of the driving transistor T3 in the second pixel circuit 12, so that the width-to-length ratio of the channel of the driving transistor T3 in the first pixel circuit 11 is greater than the width-to-length ratio of the channel of the driving transistor T3 in the second pixel circuit 12, and thus the on-state current of the driving transistor T3 in the second pixel circuit 12 is small. Therefore, charging of the first node N1 by the driving transistor T3 through the compensation transistor T2 in the second pixel circuit 12 is insufficient. After the charging is completed, a voltage at the first node N1 in the second pixel circuit 12 is lower than a voltage at the first node N1 in the first pixel circuit 11. In this way, in a case where the preset grayscale is a low grayscale, in the light-emitting phase of the second pixel circuit 12, the driving transistor T3 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated, so that the driving current passing through the driving transistor T3 in the second pixel circuit 12 increases, and the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

For example, in a case where the channel width of the driving transistor T3 in the first pixel circuit 11 is larger than the channel width of the driving transistor T3 in the second pixel circuit 12, a channel length of the driving transistor T3 in the first pixel circuit 11 may be the same as or different from a channel length of the driving transistor T3 in the second pixel circuit 12.

In some examples, a difference between the channel width of the driving transistor T3 in the first pixel circuit 11 and the channel width of the driving transistor T3 in the second pixel circuit 12 is less than or equal to 0.6 μm.

For example, the difference between the channel width of the driving transistor T3 in the first pixel circuit 11 and the channel width of the driving transistor T3 in the second pixel circuit 12 may be 0.6 μm, 0.5 μm, 0.4 μm, 0.3 μm, 0.2 μm or 0.1 μm.

With the above provision manner, in a case where the preset grayscales of the first light-emitting device 21 and the second light-emitting device 22 are the same, the width-to-length ratio of the channel of the driving transistor T3 in the second pixel circuit 12 is less than the width-to-length ratio of the channel of the driving transistor T3 in the first pixel circuit 11, and the on-state current of the driving transistor T3 in the second pixel circuit 12 is smaller than the on-state current of the driving transistor T3 in the first pixel circuit 11. Therefore, in the data writing and compensation phase of the pixel circuit, charging of the first node N1 by the driving transistor T3 through the compensation transistor T2 in the second pixel circuit 12 is insufficient. After the charging is completed, a voltage at the first node N1 in the second pixel circuit 12 is lower than a voltage at the first node N1 in the first pixel circuit 11. In this way, in a case where the preset grayscale is a low grayscale, in the light-emitting phase of the second pixel circuit 12, the driving transistor T3 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated, so that the driving current passing through the driving transistor T3 in the second pixel circuit 12 increases, and the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, a ratio of the channel width of the driving transistor T3 in the first pixel circuit 11 to the channel width of the driving transistor T3 in the second pixel circuit 12 is greater than 1 and less than or equal to 1.21.

For example, in a case where the channel width of the driving transistor T3 in the first pixel circuit 11 is 3.5 μm, the channel width of the driving transistor T3 in the second pixel circuit 12 may be 3.4 μm, 3.3 μm, 3.2 μm, 3.1 μm or 2.9 μm. In this case, the ratio of the channel width of the driving transistor T3 in the first pixel circuit 11 to the channel width of the driving transistor T3 in the second pixel circuit 12 is 1.02, 1.06, 1.09, 1.13 or 1.21.

In some embodiments, as shown in FIG. 10, a channel length of the driving transistor T3 in the first pixel circuit 11 is larger than a channel length of the driving transistor T3 in the second pixel circuit 12.

A partial structural diagram of the driving transistor T3 in the first pixel circuit 11 is shown in (a) of FIG. 10, and a partial structural diagram of the driving transistor T3 in the second pixel circuit 12 is shown in (b) of FIG. 10.

In some examples, as shown in FIGS. 4 and 8b, the channel portion of the driving transistor T3 is in a shape of a broken line, and the channel portion with the broken line shape includes portions extending in the first direction X and portions extending in the second direction Y. As shown in FIG. 8b, the channel length of the driving transistor T3 is a sum of dimensions of lengths L31, L32 and L33 of three portions of the channel extending in the first direction X and dimensions of lengths L34 and L35 of portions of the channel extending in the second direction Y (i.e., L3=L31+L32+L33+L34+L35).

With the above provision manner, the width-to-length ratio of the channel of the driving transistor T3 in the first pixel circuit 11 is greater than the width-to-length ratio of the channel of the driving transistor T3 in the second pixel circuit 12, and thus the on-state current of the driving transistor T3 in the second pixel circuit 12 is smaller than the on-state current of the driving transistor T3 in the first pixel circuit 11. Therefore, in the data writing and compensation phase of the pixel circuit, charging of the first node N1 by the driving transistor T3 through the compensation transistor T2 in the second pixel circuit 12 is insufficient. After the charging is completed, a voltage at the first node N1 in the second pixel circuit 12 is lower than a voltage at the first node N1 in the first pixel circuit 11. In this way, in a case where the preset grayscale is a low grayscale, in the light-emitting phase of the second pixel circuit 12, the driving transistor T3 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated, so that the driving current passing through the driving transistor T3 in the second pixel circuit 12 increases, and the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

For example, in a case where the channel length of the driving transistor T3 in the first pixel circuit 11 is larger than the channel length of the driving transistor T3 in the second pixel circuit 12, the channel width of the driving transistor T3 in the first pixel circuit 11 may be the same as or different from the channel width of the driving transistor T3 in the second pixel circuit 12.

In some examples, a difference between the channel length of the driving transistor T3 in the first pixel circuit 11 and the channel length of the driving transistor T3 in the second pixel circuit 12 is less than or equal to 1.4 μm.

For example, the difference between the channel length of the driving transistor T3 in the first pixel circuit 11 and the channel length of the driving transistor T3 in the second pixel circuit 12 may be 0.4 μm, 0.7 μm, 1.0 μm, 1.2 μm, or 1.4 μm.

With the above provision manner, in a case where the preset grayscales of the first light-emitting device 21 and the second light-emitting device 22 are the same, the width-to-length ratio of the channel of the driving transistor T3 in the second pixel circuit 12 is small, so that the on-state current of the driving transistor T3 in the second pixel circuit 12 is small, and the charging of the first node N1 is insufficient. Further, in the light-emitting phase, the driving transistor T3 in the second pixel circuit 12 is more fully turned on, so that the driving current passing through the driving transistor T3 increases to a certain extent, and the difference in luminous brightness between the second light-emitting device 22 and the first light-emitting device 21 is small or even tends to be the same, thereby improving the uniformity of the display substrate 100 and the display apparatus 1000 in low grayscale display conditions.

In some examples, a ratio of the channel length of the driving transistor T3 in the first pixel circuit 11 to the channel length of the driving transistor T3 in the second pixel circuit 12 is less than 1 and greater than or equal to 0.94.

For example, in a case where the channel length of the driving transistor T3 in the first pixel circuit 11 is 24 μm, the channel length of the driving transistor T3 in the second pixel circuit 12 may be 24.3 μm, 24.6 μm, 24.9 μm, 25.1 μm or 25.4 μm. In this case, the ratio of the channel length of the driving transistor T3 in the first pixel circuit 11 to the channel length of the driving transistor T3 in the second pixel circuit 12 is 0.99, 0.98, 0.96, 0.95 or 0.94.

In some embodiments, as shown in FIG. 12, a channel width of the compensation transistor T2 in the first pixel circuit 11 is larger than a channel width of the compensation transistor T2 in the second pixel circuit 12.

A partial structural diagram of the driving transistor T3 in the first pixel circuit 11 is shown in (a) of FIG. 12, and a partial structural diagram of the driving transistor T3 in the second pixel circuit 12 is shown in (b) of FIG. 12.

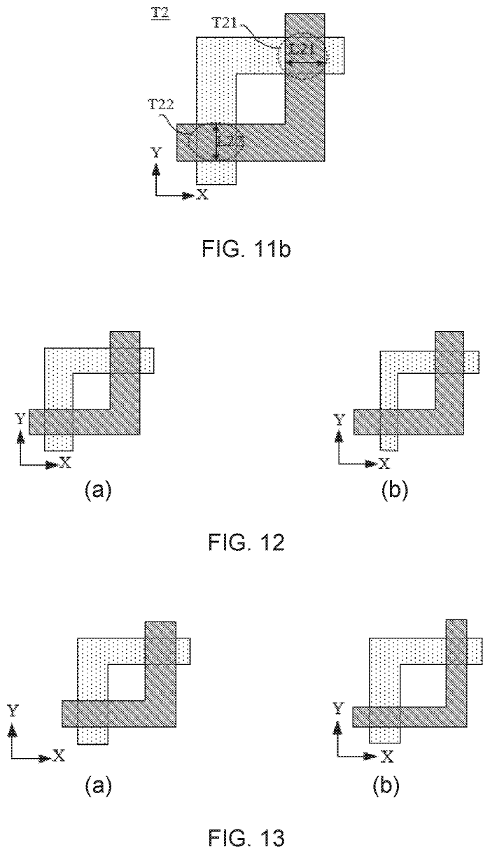

In some examples, as shown in FIG. 4, the compensation transistor T2 is a dual-gate transistor. As shown in FIG. 11a, the compensation transistor T2 includes a first compensation sub-transistor T21 and a second compensation sub-transistor T22. The channel width of the compensation transistor T2 is an average value of a channel width W21 of the first compensation sub-transistor T21 and a channel width W22 of the second compensation sub-transistor T22 (i.e., W2=(W21+W22)/2).

With the above provision manner, the channel capacitance of the compensation transistor T2 in the first pixel circuit 11 can be made smaller than the channel capacitance of the compensation transistor T2 in the second pixel circuit 12. Therefore, in a case where the compensation transistor T2 is turned off, a level of the scanning signal transmitted by the scanning signal line Gate changes from a low level to a high level. That is to say, a voltage of the gate of the compensation transistor T2 increases, and thus a voltage of the second electrode of the compensation transistor T2 connected to the first node N1 will increase accordingly. Since the channel capacitance of the compensation transistor T2 in the second pixel circuit 12 is smaller than the channel capacitance of the compensation transistor T2 in the first pixel circuit 11, in a case where the voltage of the gate of the compensation transistor T2 increases, an increased amplitude of the voltage of the channel portion of the compensation transistor T2 in the second pixel circuit 12 is smaller than an increased amplitude of the voltage of the channel portion of the compensation transistor T2 in the first pixel circuit 11. Since the channel portion of the compensation transistor T2 is connected to the first node N1 through the second electrode of the compensation transistor T2, that is, an increased amplitude of the voltage at the first node N1 in the second pixel circuit 12 is smaller than an increased amplitude of the voltage at the first node N1 in the first pixel circuit 11, so that the voltage at the first node N1 in the second pixel circuit 12 is less affected by the channel capacitor of the corresponding compensation transistor T2, and the voltage at the first node N1 in the second pixel circuit 12 is lower than the voltage at the first node N1 in the first pixel circuit 11. Thus, in the light-emitting phase, the driving transistor T3 in the second pixel circuit 12 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated. Therefore, the driving current passing through the driving transistor T3 in the second pixel circuit 12 increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, a difference between the channel width of the compensation transistor T2 in the first pixel circuit 11 and the channel width of the compensation transistor T2 in the second pixel circuit 12 is less than or equal to 0.3 μm.

For example, the difference between the channel width of the compensation transistor T2 in the first pixel circuit 11 and the channel width of the compensation transistor T2 in the second pixel circuit 12 may be 0.11 μm, 0.15 μm, 0.21 μm, 0.27 μm or 0.30 μm.

With the above provision manner, in a case where the preset grayscales of the first light-emitting device 21 and the second light-emitting device 22 are the same, the channel capacitance of the compensation transistor T2 in the second pixel circuit 12 is relatively small. Therefore, in a case where the compensation transistor T2 is turned off, a voltage of the gate of the compensation transistor T2 increases, and thus a voltage of the second electrode of the compensation transistor T2 connected to the first node N1 will increase accordingly. Since the channel capacitance of the compensation transistor T2 in the second pixel circuit 12 is relatively small, in a case where the voltage of the gate of the compensation transistor T2 increases, an increased amplitude of the voltage of the second electrode of the compensation transistor T2 is relatively small, so that the voltage at the first node N1 is less affected by the channel capacitor, an increased amplitude of the voltage at the first node N1 in the second pixel circuit 12 is relatively small, and the voltage at the first node N1 in the second pixel circuit 12 is relatively low. Further, in the light-emitting phase, the driving transistor T3 in the second pixel circuit 12 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated. Therefore, the driving current passing through the driving transistor T3 in the second pixel circuit 12 increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, a ratio of the channel width of the compensation transistor T2 in the first pixel circuit 11 to the channel width of the compensation transistor T2 in the second pixel circuit 12 is greater than 1 and less than or equal to 1.14.

For example, in a case where the channel width of the compensation transistor T2 in the first pixel circuit 11 is 2.5 μm, the channel width of the compensation transistor T2 in the second pixel circuit 12 may be 2.2 μm, 2.3 μm or 2.4 μm. In this case, the ratio of the channel width of the compensation transistor T2 in the first pixel circuit 11 to the channel width of the compensation transistor T2 in the second pixel circuit 12 is 1.14, 1.09 or 1.04.

In some examples, as shown in FIG. 13, a channel length of the compensation transistor T2 in the first pixel circuit 11 is smaller than the channel length of the compensation transistor T2 in the second pixel circuit 12.

A partial structural diagram of the driving transistor T3 in the first pixel circuit 11 is shown in (a) of FIG. 13, and a partial structural diagram of the driving transistor T3 in the second pixel circuit 12 is shown in (b) of FIG. 13.

As shown in FIG. 11b, the channel length of the compensation transistor T2 is a sum of a channel length L21 of the first compensation sub-transistor T21 and a channel length L22 of the second compensation sub-transistor T22 (i.e., L2=L21+L32).

With the above provision manner, in a case where the channel width of the compensation transistor T2 in the first pixel circuit 11 is the same as the channel width of the compensation transistor T2 in the second pixel circuit 12, the channel capacitance of the compensation transistor T2 in the first pixel circuit 11 is smaller than the channel capacitance of the compensation transistor T2 in the second pixel circuit 12. Therefore, at the moment when the compensation transistor T2 is turned off, a voltage of the gate of the compensation transistor T2 increases, and thus a voltage of the second electrode of the compensation transistor T2 connected to the first node N1 will increase accordingly. Since the channel capacitance of the compensation transistor T2 in the second pixel circuit 12 is relatively small, in a case where the voltage of the gate of the compensation transistor T2 increases, an increased amplitude of the voltage of the second electrode of the compensation transistor T2 is relatively small, so that the voltage at the first node N1 is less affected by the channel capacitor, an increased amplitude of the voltage at the first node N1 in the second pixel circuit 12 is relatively small, and the voltage at the first node N1 in the second pixel circuit 12 is relatively low. Further, in the light-emitting phase, the driving transistor T3 in the second pixel circuit 12 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated. Therefore, the driving current passing through the driving transistor T3 in the second pixel circuit 12 increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, a difference between the channel length of the compensation transistor T2 in the first pixel circuit 11 and the channel length of the compensation transistor T2 in the second pixel circuit 12 is less than or equal to 0.8 μm.

For example, the difference between the channel length of the compensation transistor T2 in the first pixel circuit 11 and the channel length of the compensation transistor T2 in the second pixel circuit 12 may be 0.1 μm, 0.2 μm, 0.5 μm, 0.7 μm or 0.8 μm.

With the above provision manner, in a case where the preset grayscales of the first light-emitting device 21 and the second light-emitting device 22 are the same, the channel capacitance of the compensation transistor T2 in the second pixel circuit 12 is relatively small. Therefore, in a case where the compensation transistor T2 is turned off, a level of the scanning signal transmitted by the scanning signal line Gate changes from a low level to a high level. That is to say, a voltage of the gate of the compensation transistor T2 increases, and thus a voltage of the second electrode of the compensation transistor T2 connected to the first node N1 will increase accordingly. Since the channel capacitance of the compensation transistor T2 in the second pixel circuit 12 is smaller than the channel capacitance of the compensation transistor T2 in the first pixel circuit 11, in a case where the voltage of the gate of the compensation transistor T2 increases, an increased amplitude of the voltage of the channel portion of the compensation transistor T2 in the second pixel circuit 12 is smaller than an increased amplitude of the voltage of the channel portion of the compensation transistor T2 in the first pixel circuit 11. Since the channel portion of the compensation transistor T2 is connected to the first node N1 through the second electrode of the compensation transistor T2, that is, an increased amplitude of the voltage at the first node N1 in the second pixel circuit 12 is smaller than an increased amplitude of the voltage at the first node N1 in the first pixel circuit 11, so that the voltage at the first node N1 in the second pixel circuit 12 is less affected by the channel capacitor of the corresponding compensation transistor T2, and the voltage at the first node N1 in the second pixel circuit 12 is lower than the voltage at the first node N1 in the first pixel circuit 11. Thus, in the light-emitting phase, the driving transistor T3 in the second pixel circuit 12 controlled by the first node N1 is more fully turned on, resulting in a relatively large starting value of the driving current passing through the driving transistor T3 in the second pixel circuit 12. Thus, the overall decrease of the value of the driving current due to a long time for pre-charging the fourth node N4 may be compensated. Therefore, the driving current passing through the driving transistor T3 in the second pixel circuit 12 increases, so that the luminous brightness of the second light-emitting device 22 may be improved, thereby reducing a difference in luminous brightness between the second light-emitting device 22 and the first light-emitting device 21 under the same preset low grayscale, and improving the uniformity of the display substrate 100 and the display apparatus 1000 in low grayscale display conditions.

In some examples, a ratio of the channel length of the compensation transistor T2 in the first pixel circuit 11 to the channel length of the compensation transistor T2 in the second pixel circuit 12 is greater than 1 and less than or equal to 1.15.

For example, in a case where the channel length of the compensation transistor T2 in the first pixel circuit 11 is 6.2 μm, the channel length of the compensation transistor T2 in the second pixel circuit 12 may be 5.4 μm, 5.5 μm, 5.7 μm, 5.8 μm or 6.1 μm. In this case, the ratio of the channel length of the compensation transistor T2 in the first pixel circuit 11 to the channel length of the compensation transistor T2 in the second pixel circuit 12 is 1.15, 1.13, 1.09, 1.07 or 1.02.

In some embodiments, as shown in FIG. 7b, the display substrate 100 further includes a plurality of leads 30. The second pixel circuit 12 and the second light-emitting device 22 are coupled by the lead.

In some examples, ends of the plurality of leads 30 are coupled to the fourth nodes N4 of the second pixel circuits 12, and other ends of the plurality of leads 30 are coupled to the first electrodes of the second light-emitting devices 22, thereby realizing coupling of the second pixel circuits 12 and the second light-emitting devices 22.

In an implementation, since the lead has a certain length, the lead will cross over circuit structures such as at least part of pixel circuits or part of the shift register unit or part of the fan-out unit. Then, a parasitic capacitor may exist between the lead and the above circuit structure, so that an electrical signal transmitted by the lead is affected by the parasitic capacitance, and thus it will take a long time for the electrical signal on the lead to be transmitted to the first electrode of the light-emitting device. Alternatively, the long lead will cause the transmitted electrical signal to be transmitted to the first electrode of the light-emitting device after undergoing a certain loss. Further, it will take a long time for the first electrode of the light-emitting device to reach a preset voltage, resulting in the light-emitting device being turned on slowly or with low luminous brightness.

In the present disclosure, the width to length ratio of the channel of the driving transistor T3 in the second pixel circuit 12 connected to the lead 30 is set to be less than the width to length ratio of the channel of the driving transistor T3 in the first pixel circuit 11, and/or the channel capacitance of the compensation transistor T2 in the second pixel circuit 12 connected to the lead 30 is set to be smaller than the channel capacitance of the compensation transistor T2 in the first pixel circuit 11, so that after the data writing and compensation phase of the pixel circuit is completed, the voltage at the first node N1 in the second pixel circuit 12 is less than the preset voltage value. Further, in the light-emitting phase, the driving transistor T3 controlled by the first node N1 is more fully turned on, resulting in a relatively large starting value of the driving current passing through the driving transistor T3. Thus, the overall decrease of the value of the driving current due to a long time for pre-charging the fourth node N4 may be compensated, so that the driving current passing through the driving transistor T3 in the second pixel circuit 12 increases, and the luminous brightness of the second light-emitting device 22 may be improved, thereby reducing a difference in luminous brightness between the second light-emitting device 22 and the first light-emitting device 21 under the same preset low grayscale, and improving the display uniformity of the display substrate 100 and the display apparatus 1000 in low grayscale display conditions.

It will be noted that the longer the length of the lead 30, the larger the area of the lead 30 directly opposite to the circuit structure such as the pixel circuit, the shift register unit or the fan-out unit, and the greater the capacitance of the parasitic capacitor formed between the lead 30 and the above circuit structure. Moreover, the longer the lead 30, the greater the loss of the electrical signal on the lead 30, the longer the time of pre-charging the fourth node N4 or the lower the starting value of the driving current, and the smaller the driving current transmitted by the lead 30.

In some examples, the width-to-length ratios of the channels of the driving transistors T3 in the second pixel circuits 12 are negatively correlated to the lengths of the leads 30 respectively connected to the second pixel circuits 12.

For example, since the plurality of second pixel circuits 12 and the second light-emitting devices 22 driven thereby have different distances therebetween, the corresponding leads 30 have different lengths. The greater the distance between one of the plurality of second pixel circuits 12 and a second light-emitting device 22 driven thereby, the longer the length of the corresponding lead 30.

For example, the lengths of the leads 30 may be 34 μm, 80 μm, 100 μm, 150 μm and 195 μm.

For example, the plurality of leads 30 may be located in the light-emitting device layer of the display substrate 100.

The “negative correlation” here means that the longer the length of the lead 30 connected to the second pixel circuit 12, the smaller the width-to-length ratio of the channel of the driving transistor T3 in the second pixel circuit 12.

With the above provision manner, in a case where the length of the lead 30 connected to the second pixel circuit 12 is longer, the width-to-length ratio of the channel of the driving transistor T3 in the second pixel circuit 12 is set to be smaller, so that the voltage at the first node N1 in the second pixel circuit 12 is lower. As a result, the driving transistor T3 controlled by the first node N1 is more fully turned on, so that the starting value of the driving current passing through the driving transistor T3 is relatively large, which makes up for a decrease in the starting value of the driving current caused by the parasitic capacitance formed between the lead 30 and the above circuit structure and the loss of the electrical signal due to the length of the lead 30. Therefore, the luminous brightness of the second light-emitting device 22 may be improved, thereby reducing a difference in luminous brightness between the second light-emitting device 22 and the first light-emitting device 21 under the same preset grayscale, and improving the display uniformity of the display substrate 100 and the display apparatus 1000.

In some examples, the channel capacitances of the compensation transistors T2 in the second pixel circuits 12 are negatively correlated to the lengths of the leads 30 respectively connected to the second pixel circuits 12.

The “negative correlation” here means that the longer the length of the lead 30 connected to the second pixel circuit 12, the smaller the channel capacitance of the compensation transistor T2 in the second pixel circuit 12.

With the above provision manner, in a case where the length of the lead 30 connected to the second pixel circuit 12 is longer, the channel capacitance of the compensation transistor T2 in the second pixel circuit 12 is set to be smaller, so that the voltage at the first node N1 in the second pixel circuit 12 is lower. As a result, the driving transistor T3 controlled by the first node N1 is more fully turned on, so that the starting value of the driving current passing through the driving transistor T3 is relatively large, which makes up for a decrease in the starting value of the driving current caused by the parasitic capacitance formed between the lead 30 and the above circuit structure and the loss of the electrical signal due to the length of the lead 30. Therefore, the luminous brightness of the second light-emitting device 22 may be improved, thereby reducing a difference in luminous brightness between the second light-emitting device 22 and the first light-emitting device 21 under the same preset grayscale, and improving the display uniformity of the display substrate 100 and the display apparatus 1000.

For example, as shown in FIG. 2, the display substrate 100 includes shift registers GOA. The plurality of first pixel circuits 11, the plurality of second pixel circuits 12 and a plurality of shift registers GOA are arranged in a plurality of rows and a plurality of columns in the display region A. The plurality of light-emitting devices 20 are arranged in a plurality of rows and a plurality of columns. Taking an example of a region on a right side of a center line NN′ of the display substrate 100, a distance between the second pixel circuit 12 in an nth column and the second light-emitting device 22 driven thereby in the top view (FIG. 7a), a distance between the second pixel circuit in an (n+1) th column and the second light-emitting device 22 driven thereby in the top view (FIG. 7a), a distance between the second pixel circuit 12 in an (n+2) th column and the second light-emitting device 22 driven thereby in the top view (FIG. 7a), . . . , increase progressively. Then, the width-to-length ratios of the channels of the driving transistors T3 in the corresponding second pixel circuits 12 decrease progressively, or the channel capacitances of the compensation transistors T2 in the corresponding second pixel circuits 12 decrease progressively.

In the present disclosure, the channel width of the driving transistor T3 in the second pixel circuit 12 is set to decrease by 0.6 μm relative to the channel width of the driving transistor T3 in the first pixel circuit 11, and in this case, both the electrical signal and driving current of the first node N1 in the first pixel circuit 11, and both the electrical signal and driving current I of the first node N1 in the second pixel circuit 12 are simulated and calculated. The simulation results are shown in FIG. 14a.

In the present disclosure, the channel length of the driving transistor T3 in the second pixel circuit 12 is set to increase by 1.4 μm relative to the channel length of the driving transistor T3 in the first pixel circuit 11, and in this case, both the electrical signal and driving current I of the first node N1 in the first pixel circuit 11, and both the electrical signal and driving current of the first node N1 in the second pixel circuit 12 are simulated and calculated. The simulation results are shown in FIG. 14b.

In the present disclosure, the channel width of the compensation transistor T2 in the second pixel circuit 12 is set to decrease by 0.3 μm relative to the channel width of the compensation transistor T2 in the first pixel circuit 11, and in this case, both the electrical signal and driving current I of the first node N1 in the first pixel circuit 11, and both the electrical signal and driving current of the first node N1 in the second pixel circuit 12 are simulated and calculated. The simulation results are shown in FIG. 14c.

In the present disclosure, the channel length of the compensation transistor T2 in the second pixel circuit 12 is set to decrease by 0.8 μm relative to the channel length of the compensation transistor T2 in the first pixel circuit 11, and in this case, both the electrical signal and driving current I of the first node N1 in the first pixel circuit 11, and both the electrical signal and driving current of the first node N1 in the second pixel circuit 12 are simulated and calculated. The simulation results are shown in FIG. 14d.

It can be seen from FIGS. 14a to 14b that for the driving transistor T3 in the second pixel circuit 12 relative to the driving transistor T3 in the first pixel circuit 11, the channel width decreases by 0.6 μm or the channel length increases by 1.4 μm. Though simulation testing and calculation, the voltage UN12 at the first node N1 in the second pixel circuit 12 is smaller than the voltage UN11 at the first node N1 in the first pixel circuit 11, the turn-on time t2 of the second pixel circuit 12 is later than the turn-on time t1 of the first pixel circuit 11, and the starting value of the driving current I2 of the second pixel circuit 12 is greater than the starting value of the driving current I1 of the first pixel circuit 11.

It will be noted that the turn-on time of the pixel circuit refers to the time when the driving current is generated and the magnitude of the driving current tends approximately stable. The magnitude of the driving current of the pixel circuit is an average value of the driving currents in a light-emitting phase. Taking FIG. 14a as an example, the driving current I2 of the second pixel circuit 12 is the average value of the driving currents within an effective level range of the enable signal EM (corresponding to a range between two square waves in the figure, approximately in a range of 16.8 ms to 33.5 ms).

It can be seen that for the driving transistor T3 in the second pixel circuit 12 relative to the driving transistor T3 in the first pixel circuit 11, a decrease of 0.6 μm in channel width or an increase of 1.4 μm in channel length may make the voltage at the first node N1 in the second pixel circuit 12 decrease, so that the driving transistor T3 in the second pixel circuit 12 is more fully turned on, and thus the starting value of the driving current of the second pixel circuit 12 increases to a certain extent, which makes up for a decrease in the driving current caused by the later turn-on time. Therefore, the driving current of the second pixel circuit 12 increases to a certain extent, so that the driving current of the second pixel circuit 12 and the driving current of the first pixel circuit 11 tends to be consistent, thereby improving the display uniformity of the display substrate 100 and the display apparatus 1000.

It can be seen from FIGS. 14c to 14d that for the compensation transistor T2 in the second pixel circuit 12 relative to the compensation transistor T2 in the first pixel circuit 11, the channel width decreases by 0.3 μm or the channel length decreases by 0.8 μm. Though simulation testing and calculation, the voltage UN12 at the first node N1 in the second pixel circuit 12 is smaller than the voltage UN11 at the first node N1 in the first pixel circuit 11, the turn-on time of the second pixel circuit 12 is later than the turn-on time of the first pixel circuit 11, and the starting value of the driving current I2 of the second pixel circuit 12 is greater than the starting value of the driving current I1 of the first pixel circuit 11.

It can be seen that for the compensation transistor T2 in the second pixel circuit 12 relative to the compensation transistor T2 in the first pixel circuit 11, a decrease of 0.3 μm in channel width or a decrease of 0.8 μm in channel length may make the voltage at the first node N1 in the second pixel circuit 12 decrease, so that the driving transistor T3 in the second pixel circuit 12 is more fully turned on, and thus the driving current of the second pixel circuit 12 increases to a certain extent, which makes up for a decrease in the driving current caused by the later turn-on time. Therefore, the driving current of the second pixel circuit 12 increases to a certain extent, so that the driving current of the second pixel circuit 12 and the driving current of the first pixel circuit 11 tends to be consistent, thereby improving the display uniformity of the display substrate 100 and the display apparatus 1000.

It will be noted that the pixel circuit 10 and the light-emitting device 20 driven thereby constitute a sub-pixel. The first pixel circuit 11 and the first light-emitting device 21 driven thereby constitute a first sub-pixel, and the second pixel circuit 12 and the second light-emitting device 22 driven thereby constitute a second sub-pixel. Under the same preset grayscale, colors of lights emitted by sub-pixels are different, and the driving currents required are also different.

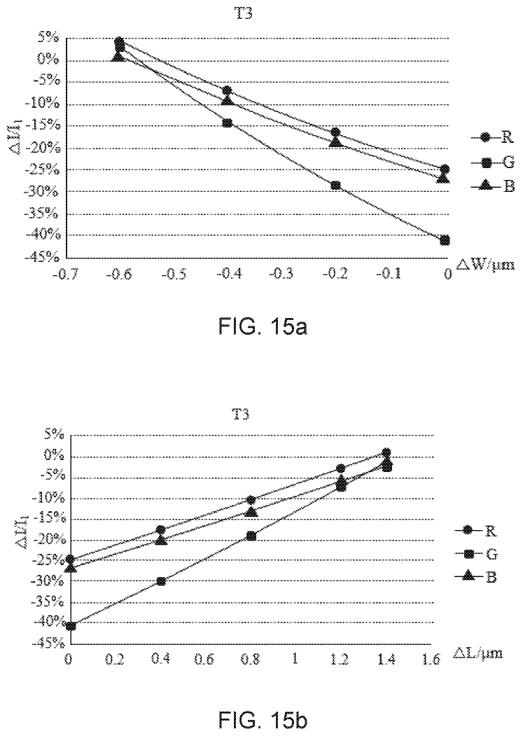

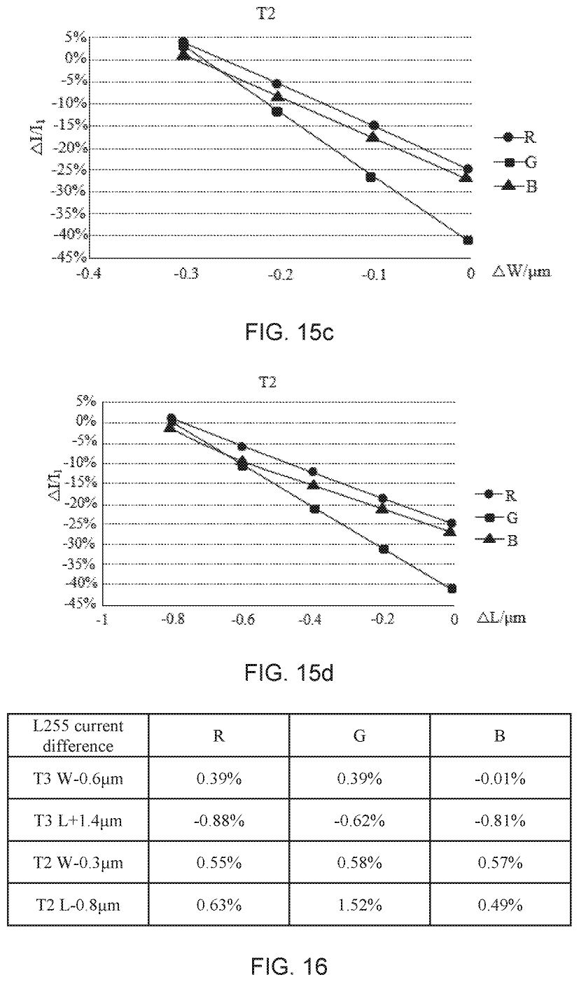

Therefore, the present disclosure calculates and draws current differences ΔI/I1 of driving currents of second sub-pixels of different colors corresponding to driving transistors T3 in different second pixel circuits 12 and compensation transistors T2 in different second pixel circuits 12, specifically, as shown in FIGS. 15a to 15d.

It will be noted that in the current difference ΔI/I1 of the driving current, I1 is a driving current of a first pixel circuit 11, and ΔI is a difference between a driving current I2 of a second pixel circuit 12 and the driving current 11 of the first pixel circuit 11.

Specifically, the channel widths W of the driving transistors T3 in the second pixel circuits 12 are set to sequentially decrease by 0.2 μm, 0.4 μm and 0.6 μm relative to the channel width of the driving transistor T3 in the first pixel circuit 11, and then the progressive decrease of the channel widths versus the current differences of the driving currents of the second sub-pixels of different colors are plotted, resulting in FIG. 15a. The channel lengths L of the driving transistors T3 in the second pixel circuits 12 are set to sequentially increase by 0.4 μm, 0.8 μm, 1.2 μm and 1.4 μm relative to the channel length of the driving transistor T3 in the first pixel circuit 11, and then the progressive increase of the channel lengths versus the current differences of the driving currents of the second sub-pixels of different colors are plotted, resulting in FIG. 15b. The channel widths W of the compensation transistors T2 in the second pixel circuits 12 are set to sequentially decrease by 0.1 μm, 0.2 μm and 0.3 μm relative to the channel width of the compensation transistor T2 in the first pixel circuit 11, and then the progressive decrease of the channel widths versus the current differences of the driving currents of the second sub-pixels of different colors are plotted, resulting in FIG. 15c. The channel lengths L of the compensation transistors T2 in the second pixel circuits 12 are set to sequentially decrease by 0.2 μm, 0.3 μm, 0.6 μm and 0.8 μm relative to the channel length of the compensation transistor T2 in the first pixel circuit 11, and then the progressive decrease of the channel lengths versus the current differences of the driving currents of the second sub-pixels of different colors are plotted, resulting in FIG. 15d.

It will be noted that in FIGS. 15a to 15d, R represents a red second sub-pixel, G represents a green second sub-pixel, and B represents a blue second sub-pixel. ΔW in FIG. 15a represents a difference between the channel width of the driving transistor T3 in the second pixel circuit 12 and the channel width of the driving transistor T3 in the first pixel circuit 11. ΔL in FIG. 15b represents a difference between the channel length of the driving transistor T3 in the second pixel circuit 12 and the channel length of the driving transistor T3 in the first pixel circuit 11. ΔW in FIG. 15c represents a difference between the channel width of the compensation transistor T2 in the second pixel circuit 12 and the channel width of the compensation transistor T2 in the first pixel circuit 11. ΔL in FIG. 15d represents a difference between the channel length of the compensation transistor T2 in the second pixel circuit 12 and the channel length of the compensation transistor T2 in the first pixel circuit 11. For convenience of description, the differences in channel length and channel width of the driving transistors T3 between the second pixel circuit 12 and the first pixel circuit 11 and the differences in channel length and channel width of the compensation transistors T2 between the second pixel circuit 12 and the first pixel circuit 11 are collectively referred to as a channel variation of the second pixel circuit 12 below.

It can be seen from FIGS. 15a to 15d that as the channel variation of the second pixel circuit 12 increases, the current difference ΔI/I1 of the driving current of the second pixel circuit 12 presents a gradually decreasing trend. Taking the green second sub-pixel G in FIG. 15a as an example, during the channel variation of the second pixel circuit 12 progressively changes from 0 μm to −0.6 μm, the current difference ΔI/I1 of the driving current of the second pixel circuit 12 in the green second sub-pixel G changes from −40% to approximately 0%. In a case where the difference between the channel width of the driving transistor T3 in the second pixel circuit 12 and the channel width of the driving transistor T3 in the first pixel circuit 11 is 0.6 μm, the driving current of the second pixel circuit 12 is approximately equal to the driving current of the first pixel circuit 11, thereby greatly improving the display uniformity of the display substrate 100 and the display apparatus 1000.

In addition, it can be seen from FIGS. 15a to 15d that as the channel variation of the second pixel circuit 12 increases, the change trends of the second sub-pixels of different colors are consistent. Taking FIG. 15b as an example, during the channel variation of the second pixel circuits 12 progressively changes from 0 μm to 1.6 μm, the current difference ΔI/I1 of the driving current of the second pixel circuit 12 in the green second sub-pixel G changes from −40% to approximately 0%, the current difference ΔI/I1 of the driving current of the second pixel circuit 12 in the red second sub-pixel R changes from −25% to approximately 0%, and the current difference ΔI/I1 of the driving current of the second pixel circuit 12 in the blue second sub-pixel B changes from −25% to approximately 0%. In a case where the channel variation is 1.6 μm, the current differences ΔI/I1 of the driving currents corresponding to the green second sub-pixel G, the red second sub-pixel R and the blue second sub-pixel B all tend to 0. It can be seen that, the channel variations of the second sub-pixels of different colors are applicable to the above channel variation range, i.e., a range of 0 μm to 1.6 μm. Moreover, in the case where the channel variation is 1.6 μm, the current difference between the driving current of the second pixel circuit 12 and the driving current of the first pixel circuit 11 has the optimum improvement effect, and the display uniformity of the display substrate 100 and the display apparatus 1000 may be greatly improved.

The above FIGS. 14a to 14d and FIGS. 15a to 15d are all simulations and calculations carried out under the condition of preset low grayscale. Since the current difference of the driving current will be different under different preset grayscales, the present disclosure calculates current differences corresponding to the channel variations of the above second pixel circuits 12 under a relatively high grayscale (the preset grayscale is L255), and the calculated results are shown in FIG. 16.

In FIG. 16, “T3 W−0.6 μm” indicates that the difference between the channel width of the driving transistor T3 in the second pixel circuit 12 and the channel width of the driving transistor T3 in the first pixel circuit 11 is −0.6 μm, “T3 L+1.4 μm” indicates that the difference between the channel length of the driving transistor T3 in the second pixel circuit 12 and the channel length of the driving transistor T3 in the first pixel circuit 11 is +1.4 μm, “T2 W−0.3 μm” indicates that the difference between the channel width of the compensation transistor T2 in the second pixel circuit 12 and the channel width of the compensation transistor T2 in the first pixel circuit 11 is −0.3 μm, and “T2 L−0.8 μm” indicates that the difference between the channel length of the compensation transistor T2 in the second pixel circuit 12 and the channel length of the compensation transistor T2 in the first pixel circuit 11 is −0.8 μm. “R” represents the red second sub-pixel, “G” represents the green second sub-pixel, and “B” represents the blue second sub-pixel.

It can be seen from FIG. 16 that in a case of the preset grayscale being L255, the current differences of the driving currents of the second sub-pixels of different colors is small and approaches 0. It can be seen that within the range of the channel variation of the second pixel circuit 12 provided in the present disclosure, both the low grayscale display and the high grayscale display of the display substrate 100 may achieve the relatively uniform display effect, which significantly improves the display uniformity of the display substrate 100 and the display apparatus 1000.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display substrate, comprising a plurality of pixel circuits and a plurality of light-emitting devices; and the pixel circuits each including a driving transistor and a compensation transistor coupled to the driving transistor; wherein
the plurality of pixel circuits include a plurality of first pixel circuits and a plurality of second pixel circuits;
the plurality of light-emitting devices include a plurality of first light-emitting devices and a plurality of second light-emitting devices;
a first pixel circuit is coupled to a first light-emitting device, and the first pixel circuit is disposed at least partially directly opposite to the first light-emitting device;
a second pixel circuit is coupled to a second light-emitting device, and an orthographic projection of the second pixel circuit on a plane where the display substrate is located and an orthographic projection of the second light-emitting device on the plane where the display substrate is located have no overlap; wherein the first pixel circuit and the second pixel circuit satisfy at least one of:
a width-to-length ratio of a channel of a driving transistor in the first pixel circuit is greater than a width-to-length ratio of a channel of a driving transistor in the second pixel circuit; and
a channel capacitance of a compensation transistor in the first pixel circuit is larger than a channel capacitance of a compensation transistor in the second pixel circuit.

2. The display substrate according to claim 1, wherein a channel width of the driving transistor in the first pixel circuit is larger than a channel width of the driving transistor in the second pixel circuit.

3. The display substrate according to claim 2, wherein
a difference between the channel width of the driving transistor in the first pixel circuit and the channel width of the driving transistor in the second pixel circuit is less than or equal to 0.6 μm.

4. The display substrate according to claim 1, wherein a ratio of a channel width of the driving transistor in the first pixel circuit to a channel width of the driving transistor in the second pixel circuit is greater than 1 and less than or equal to 1.21.

5. The display substrate according to claim 1, wherein a channel length of the driving transistor in the first pixel circuit is smaller than a channel length of the driving transistor in the second pixel circuit.

6. The display substrate according to claim 5, wherein a difference between the channel length of the driving transistor in the first pixel circuit and the channel length of the driving transistor in the second pixel circuit is less than or equal to 1.4 μm.

7. The display substrate according to claim 1, wherein a ratio of a channel length of the driving transistor in the first pixel circuit to a channel length of the driving transistor in the second pixel circuit is less than 1 and greater than or equal to 0.94.

8. The display substrate according to claim 1, wherein a channel width of the compensation transistor in the first pixel circuit is larger than a channel width of the compensation transistor in the second pixel circuit.

9. The display substrate according to claim 8, wherein a difference between the channel width of the compensation transistor in the first pixel circuit and the channel width of the compensation transistor in the second pixel circuit is less than or equal to 0.3 μm.

10. The display substrate according to claim 8, wherein a ratio of the channel width of the compensation transistor in the first pixel circuit to the channel width of the compensation transistor in the second pixel circuit is greater than 1 and less than or equal to 1.14.

11. The display substrate according to claim 1, wherein a channel length of the compensation transistor in the first pixel circuit is larger than a channel length of the compensation transistor in the second pixel circuit.

12. The display substrate according to claim 11, wherein a difference between the channel length of the compensation transistor in the first pixel circuit and the channel length of the compensation transistor in the second pixel circuit is less than or equal to 0.8 μm.

13. The display substrate according to claim 11, wherein a ratio of the channel length of the compensation transistor in the first pixel circuit to the channel length of the compensation transistor in the second pixel circuit is greater than 1 and less than or equal to 1.15.

14. The display substrate according to claim 1, further comprising a plurality of leads; wherein
the second pixel circuit is coupled to the second light-emitting device by a lead.

15. The display substrate according to claim 14, wherein width-to-length ratios of channels of driving transistors in the second pixel circuits are negatively correlated to lengths of the leads respectively connected to the second pixel circuits;
and/or channel capacitances of compensation transistors in the second pixel circuits are negatively correlated to the lengths of the leads respectively connected to the second pixel circuits.

16. The display substrate according to claim 1, further comprising a first reset signal line, a first initial signal line, a scanning signal line, a data signal line, an enable signal line, a first voltage signal line, a second reset signal line and a second initial signal line; wherein the pixel circuits each further include a first reset transistor, a first light emission control transistor, a second light emission control transistor, a second reset transistor, a switch transistor and a storage capacitor;
a gate of the first reset transistor is coupled to the first reset signal line, a first electrode of the first reset transistor is coupled to the first initial signal line, and a second electrode of the first reset transistor is coupled to a first node; and the first reset transistor is configured to transmit a first initial signal provided by the first initial signal line to the first node under control of a first reset signal provided by the first reset signal line;
a gate of the switch transistor is coupled to the scanning signal line, a first electrode of the switch transistor is coupled to the data signal line, and a second electrode of the switch transistor is coupled to a second node; and the switch transistor is configured to transmit a data signal provided by the data signal line to the second node under control of a scanning signal provided by the scanning signal line;
a gate of the first light emission control transistor is coupled to the enable signal line, a first electrode of the first light emission control transistor is coupled to the first voltage signal line, and a second electrode of the first light emission control transistor is coupled to the second node; and the first light emission control transistor is configured to transmit a first voltage signal provided by the first voltage signal line to the second node under control of an enable signal provided by the enable signal line;
a gate of the driving transistor is coupled to the first node, a first electrode of the driving transistor is coupled to the second node, and a second electrode of the driving transistor is coupled to a third node; and the driving transistor is configured to transmit an electrical signal at the second node to the third node under control of an electrical signal at the first node;
a gate of the compensation transistor is coupled to the scanning signal line, a first electrode of the compensation transistor is coupled to the third node, and a second electrode of the compensation transistor is coupled to the first node; and the compensation transistor is configured to transmit an electrical signal at the third node to the first node under the control of the scanning signal;
a first electrode plate of the storage capacitor is coupled to the first voltage signal line, and a second electrode plate of the storage capacitor is coupled to the first node;
a gate of the second light emission control transistor is coupled to the enable signal line, a first electrode of the second light emission control transistor is coupled to the third node, and a second electrode of the second light emission control transistor is coupled to a fourth node; and the second light emission control transistor is configured to transmit the electrical signal at the third node to the fourth node under the control of the enable signal; and
a gate of the second reset transistor is coupled to the second reset signal line, a first electrode of the second reset transistor is coupled to the second initial signal line, and a second electrode of the second reset transistor is coupled to the fourth node; and the second reset transistor is configured to transmit a second initial signal provided by the second initial signal line to the fourth node under control of a second reset signal provided by the second reset signal line.

17. A display apparatus, comprising the display substrate according to claim 1.
